(19) United States
(12) Patent Application Publication
(10) Pub. No.: US 2026/0128722 A1
(43) Pub. Date: May 7, 2026

(54) PIEZOELECTRIC DEVICE

(71) Applicant: Murata Manufacturing Co., Ltd., Nagaokakyo-shi (JP)

(72) Inventors: Shintaro KUBO, Nagaokakyo-shi (JP); Yutaka KISHIMOTO, Nagaokakyo-shi (JP); Masashi OMURA, Nagaokakyo-shi (JP); Yuzo KISHI, Nagaokakyo-shi (JP)

(21) Appl. No.: 19/437,418

(22) Filed: Dec. 31, 2025

Related U.S. Application Data
(63) Continuation of application No. PCT/JP2024/026037, filed on Jul. 19, 2024.

(30) Foreign Application Priority Data
Jul. 20, 2023 (JP) 2023-118139

(51) Int. Cl. H03H 9/13; H03H 9/15

(52) U.S. Cl. CPC H03H 9/13; H03H 9/15

(57) ABSTRACT

A piezoelectric device includes a piezoelectric layer including upper and lower surfaces in a first direction, a support on a lower surface side of the piezoelectric layer, and a functional electrode on the upper or second surface of the piezoelectric layer. The piezoelectric layer or the support includes a space portion in a region overlapping a portion of the functional electrode. When a region of the piezoelectric layer overlapping the space portion and the functional electrode in plan view in the first direction is a first portion and a region of the piezoelectric layer overlapping the space portion in plan view in the first direction and not overlapping the functional electrode in plan view in the first direction is a second portion, a maximum thickness of the second portion is larger than a minimum thickness of the first portion.

### CROSS REFERENCE TO RELATED APPLICATIONS

This application claims the benefit of priority to Japanese Patent Application No. 2023-118139 filed on Jul. 20, 2023 and is a Continuation Application of PCT Application No. PCT/JP2024/026037 filed on Jul. 19, 2024. The entire contents of each application are hereby incorporated herein by reference.

### BACKGROUND OF THE INVENTION

### 1. Field of the Invention

The present invention relates to piezoelectric devices.

### 2. Description of the Related Art

Japanese Unexamined Patent Application Publication No. 2023-62889 discloses a thin-film piezoelectric resonance device including a piezoelectric layer with a portion located at a position overlapping a cavity of a support substrate that differs from another portion in thickness.

In the piezoelectric layer of the thin-film piezoelectric resonance device according to Japanese Unexamined Patent Application Publication No. 2023-62889, a strain may be caused at the boundary between the region where a functional electrode is provided and the region where the functional electrode is not provided, thus damaging the piezoelectric layer.

### SUMMARY OF THE INVENTION

Example embodiments of the present invention provide piezoelectric devices each able to reduce or prevent a piezoelectric layer from being damaged.

A piezoelectric device according to an example embodiment of the present invention includes a piezoelectric layer including a thickness in a first direction, an upper surface being one surface of the piezoelectric layer in the first direction, and a lower surface being another surface of the piezoelectric layer in the first direction, a support on a lower surface side of the piezoelectric layer, and at least one functional electrode on at least one of the upper surface and the lower surface of the piezoelectric layer. The piezoelectric layer or the support includes a space portion in a region overlapping at least a portion of the at least one functional electrode. When a region of the piezoelectric layer that overlaps the space portion and the at least one functional electrode in plan view in the first direction is a first portion and a region of the piezoelectric layer that overlaps the space portion in plan view in the first direction and that does not overlap the at least one functional electrode in plan view in the first direction is a second portion, a maximum thickness of the second portion is larger than a minimum thickness of the first portion.

According to example embodiments of the present invention, piezoelectric devices each able to reduce or prevent a piezoelectric layer from being damaged are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view illustrating an example of a piezoelectric device according to Example Embodiment 1 of the present invention.

FIG. 2 is a schematic sectional view taken along line II-II in FIG. 1.

FIG. 3 is a diagram illustrating the distribution of the thickness of a piezoelectric layer according to Example Embodiment 1 of the present invention.

FIG. 4 is an explanatory diagram for describing an example of a method for manufacturing the piezoelectric device according to Example Embodiment 1 of the present invention.

FIG. 5 is a plan view illustrating a piezoelectric device according to Modification 1 of Example Embodiment 1 of the present invention.

FIG. 6 is a schematic sectional view taken along line VI-VI in FIG. 5.

FIG. 7 is a diagram illustrating the distribution of the thickness of a piezoelectric layer according to Modification 1 of Example Embodiment 1 of the present invention.

FIG. 8 is an explanatory diagram for describing a method for manufacturing the piezoelectric device according to Modification 1 of Example Embodiment 1 of the present invention.

FIG. 9 is a schematic sectional view illustrating a piezoelectric device according to Example Embodiment 2 of the present invention.

FIG. 10 is a diagram illustrating the distribution of the thickness of a piezoelectric layer according to Example Embodiment 2 of the present invention.

FIG. 11 is an explanatory diagram for describing an example of a method for manufacturing the piezoelectric device according to Example Embodiment 2 of the present invention.

FIG. 12 is a schematic sectional view illustrating a piezoelectric device according to Modification 2 of Example Embodiment 2 of the present invention.

FIG. 13 is a diagram illustrating the distribution of the thickness of a piezoelectric layer according to Modification 2 of Example Embodiment 2 of the present invention.

FIG. 14 is an explanatory diagram for describing a method for manufacturing the piezoelectric device according to Modification 2 of Example Embodiment 2 of the present invention.

FIG. 15 is a schematic sectional view illustrating a piezoelectric device according to Modification 3 of Example Embodiment 2 of the present invention.

FIG. 16 is a schematic sectional view illustrating a piezoelectric device according to Modification 4 of Example Embodiment 2 of the present invention.

FIG. 17 is a schematic sectional view illustrating a piezoelectric device according to Example Embodiment 3 of the present invention.

FIG. 18 is a diagram illustrating the distribution of the thickness of a piezoelectric layer according to Example Embodiment 3 of the present invention.

FIG. 19 is an explanatory diagram for describing an example of a method for manufacturing the piezoelectric device according to Example Embodiment 3 of the present invention.

FIG. 20 is a diagram for describing a step of thinning the piezoelectric layer according to Example embodiment 3 of the present invention.

FIG. 21 is a diagram for describing the step of thinning the piezoelectric layer according to Example Embodiment 3 of the present invention.

FIG. 22 is a schematic sectional view illustrating a piezoelectric device according to Modification 5 of Example Embodiment 3 of the present invention.

FIG. 23 is a diagram illustrating the distribution of the thickness of a piezoelectric layer according to Modification 5 of Example Embodiment 3 of the present invention.

FIG. 24 is an explanatory diagram for describing a method for manufacturing the piezoelectric device according to Modification 5 of Example Embodiment 3 of the present invention.

FIG. 25 is a diagram for describing a step of thinning the piezoelectric layer according to Modification 5 of Example Embodiment 3 of the present invention.

FIG. 26 is a schematic sectional view illustrating a piezoelectric device according to Example Embodiment 4 of the present invention.

FIG. 27 is an explanatory diagram for describing a method for manufacturing the piezoelectric device according to Example Embodiment 4 of the present invention.

FIG. 28 is a schematic sectional view illustrating a piezoelectric device according to Example Embodiment 5 of the present invention.

FIG. 29 is an explanatory diagram for describing an example of a method for manufacturing the piezoelectric device according to Example Embodiment 5 of the present invention.

FIG. 30 is a schematic plan view illustrating a piezoelectric device according to Example Embodiment 6 of the present invention.

FIG. 31 is a schematic plan view illustrating a piezoelectric device according to Example Embodiment 7 of the present invention.

FIG. 32 is a schematic sectional view illustrating a piezoelectric device according to Example Embodiment 8 of the present invention.

FIG. 33 is an explanatory diagram for describing an example of a method for manufacturing the piezoelectric device according to Example embodiment 8 of the present invention.

FIG. 34 is a schematic sectional view illustrating a piezoelectric device according to Modification 6 of Example Embodiment 8 of the present invention.

FIG. 35 is a schematic sectional view illustrating a piezoelectric device according to Modification 7 of Example Embodiment 8 of the present invention.

### DETAILED DESCRIPTION OF THE EXAMPLE EMBODIMENTS

Example embodiments and modifications thereof of the present invention will be described in detail below with reference to the drawings. The present invention is not limited by the example embodiments and modifications thereof. The example embodiments and modifications thereof described in the present disclosure are merely examples. From Example Embodiment 2 and in modifications in which the configurations of different example embodiments can be partially replaced or combined, points in common with Example Embodiment 1 are not described, and only different points are described. In particular, the same or similar advantageous effects resulting from the same or similar configurations are not described in each example embodiment.

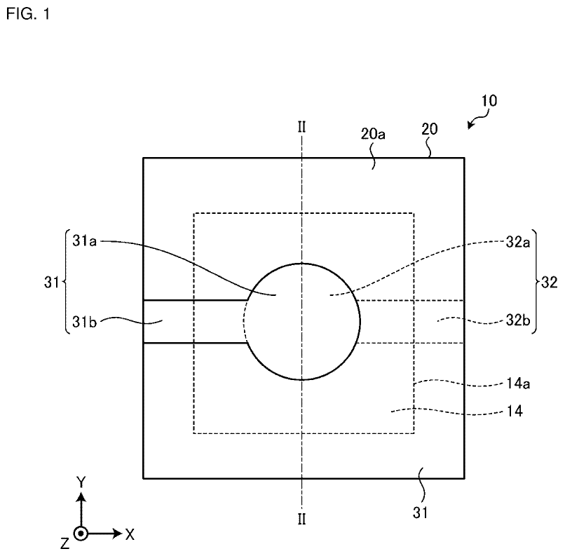

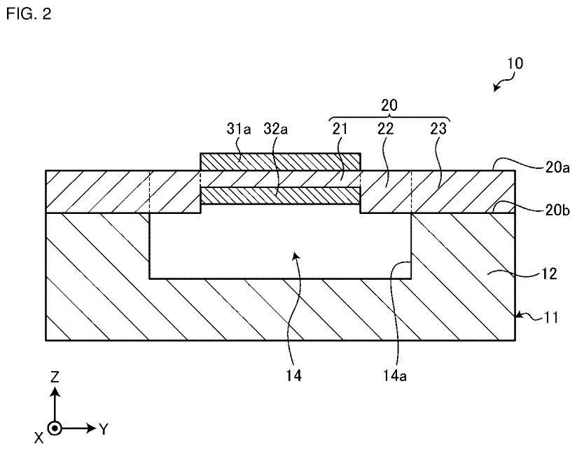

FIG. 1 is a schematic plan view illustrating an example of a piezoelectric device according to Example Embodiment 1 of the present invention. FIG. 2 is a schematic sectional view taken along line II-II in FIG. 1. A piezoelectric device 10 according to Example Embodiment 1 includes a support 11, a piezoelectric layer 20, an upper electrode 31, and a lower electrode 32. The piezoelectric device 10 is a piezoelectric element using a bulk wave, that is, a bulk acoustic wave (BAW) element. In the following description, the thickness direction of the piezoelectric layer 20 is the Z direction, a direction orthogonal to the Z direction is the X direction, and a direction orthogonal to the Z direction and the X direction is the Y direction.

The piezoelectric layer 20 is a flat layer including an upper surface 20a and a lower surface 20b opposite to the upper surface 20a. The upper surface 20a is a first main surface of the piezoelectric layer 20. The lower surface 20b is a second main surface of the piezoelectric layer 20. In Example Embodiment 1, the piezoelectric layer 20 is a substrate made of a single crystal of, for example, lithium niobate (LiNbO₃), lithium tantalate (LiTaO₃), or quartz crystal capable of exciting a bulk wave. Details of the thickness of the piezoelectric layer 20 will be described later.

As illustrated in FIG. 1, the upper electrode 31 is provided on the upper surface 20a of the piezoelectric layer 20. The upper electrode 31 is an example of a “functional electrode”. The upper electrode 31 includes a circular main electrode portion 31a and an extension portion 31b extending in the X direction from the main electrode portion 31a. The upper electrode 31 is made of a metal such as, for example, aluminum (Al), platinum (Pt), copper (Cu), tungsten (W), or molybdenum (Mo) or an alloy thereof. The upper electrode 31 may include an adhesion layer made of, for example, titanium (Ti) or nickel chromium alloy (NiCr).

As illustrated in FIG. 2, the lower electrode 32 is provided on the lower surface 20b of the piezoelectric layer 20. The lower electrode 32 is an example of the “functional electrode”. The lower electrode 32 includes a circular main electrode portion 32a and an extension portion 32b extending in the X direction from the main electrode portion 32a. The lower electrode 32 is made of a metal such as, for example, Al, Pt, Cu, W, or Mo or an alloy thereof. The lower electrode 32 may include an adhesion layer made of, for example, Ti or NiCr.

In Example Embodiment 1, in plan view in the Z direction, the circular main electrode portion 31a of the upper electrode 31 and the circular main electrode portion 32a of the lower electrode 32 overlap each other. In other words, the piezoelectric layer 20 is located between the circular main electrode portion 31a of the upper electrode 31 and the circular main electrode portion 32a of the lower electrode 32. Thus, a bulk wave is propagated in a region between the circular main electrode portion 31a of the upper electrode 31 and the circular main electrode portion 32a of the lower electrode 32. The shape of each of the upper electrode 31 and the lower electrode 32 is merely an example, and the shape of each of the upper electrode 31 and the lower electrode 32 is not limited thereto. In the following description, in plan view in the Z direction, the region where the upper electrode 31 and the lower electrode 32 overlap each other may be referred to as an excitation region.

The support 11 faces the lower surface 20b of the piezoelectric layer 20. In Example Embodiment 1, the support 11 includes a support substrate 12. The support substrate 12 is a substrate made of, for example, silicon (Si) or quartz crystal.

The support 11 includes a space portion 14. In Example Embodiment 1 in FIG. 2, the space portion 14 is a space in the recess of the support substrate 12 provided on the piezoelectric layer 20 side. The space portion 14 is provided so as to overlap the excitation region in plan view in the Z direction. Thus, a bulk wave is reflected by the space portion 14. In Example Embodiment 1, the inside of the space portion 14 is a vacuum and is sealed.

In the following description, in plan view in the Z direction, a boundary 14a between a region overlapping the space portion 14 and a region not overlapping the space portion 14 is the boundary 14a of the space portion. In Example Embodiment 1 in FIG. 1, the shape of the region overlapping the space portion 14 in plan view in the Z direction is a rectangular or substantially rectangular shape, but is merely an example, and may be a different shape such as a circular shape.

The thickness of the piezoelectric layer 20 will be described below. In the following description, the region of the piezoelectric layer 20 that overlaps the space portion 14 and the upper electrode 31 or the lower electrode 32 in plan view in the Z direction is a first portion 21. The portion of the piezoelectric layer 20 that overlaps the space portion 14 in plan view in the Z direction and that does not overlap the upper electrode 31 or the lower electrode 32 in plan view in the Z direction is a second portion 22. The portion of the piezoelectric layer 20 that does not overlap the space portion 14 or the excitation region in plan view in the Z direction is a third portion 23. In addition, in the following description, a thickness means a length in a thickness direction, that is, the Z direction. An “average thickness” means the average value of thicknesses. A “maximum thickness” means the maximum value of thicknesses. A “minimum thickness” means the minimum value of thicknesses. Here, the thickness levels of the piezoelectric layer 20 can be compared by observing a section of the piezoelectric device with a scanning electron microscope (SEM).

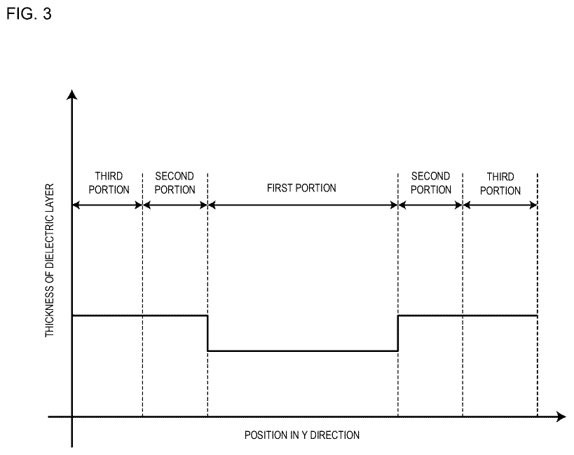

FIG. 3 is a diagram illustrating the distribution of the thickness of a piezoelectric layer according to Example Embodiment 1. More specifically, FIG. 3 is a diagram illustrating the distribution of the thickness of the piezoelectric layer 20 at each corresponding position in the Y direction in the section of FIG. 2. As illustrated in FIG. 3, the maximum thickness of the second portion 22 is larger than the minimum thickness of the first portion 21. In Example Embodiment 1, the thickness of the second portion 22 of the piezoelectric layer 20 is larger than the thickness of the first portion 21 of the piezoelectric layer 20. Thus, it is possible to reduce or prevent a strain from being caused on the piezoelectric layer 20 at the boundary between the first portion 21 and the second portion 22 and to thus reduce or prevent the piezoelectric layer 20 from being damaged.

As described above, the piezoelectric device according to Example Embodiment 1 includes the piezoelectric layer including a thickness in a first direction, the upper surface being one surface of the piezoelectric layer in the first direction, and the lower surface being the other surface of the piezoelectric layer in the first direction, the support on the lower surface side of the piezoelectric layer, and at least one functional electrode on at least one of the upper surface and the lower surface of the piezoelectric layer. The piezoelectric layer or the support includes the space portion in a region overlapping at least a portion of the at least one functional electrode. When the region of the piezoelectric layer that overlaps the space portion and the at least one functional electrode in plan view in the first direction is the first portion and the region of the piezoelectric layer that overlaps the space portion in plan view in the first direction and that does not overlap the at least one functional electrode in plan view in the first direction is the second portion, the maximum thickness of the second portion is larger than the minimum thickness of the first portion. Thus, it is possible to reduce or prevent a strain from being caused on the piezoelectric layer at the boundary between the region overlapping the at least one functional electrode in plan view in the first direction and the region not overlapping the at least one functional electrode in plan view in the first direction, that is, the boundary between the first portion and the second portion, and to thus reduce or prevent the piezoelectric layer from being damaged.

According to an example embodiment of the present invention, the maximum thickness of the second portion is larger than the average thickness of the at least one functional electrode. Thus, even when the piezoelectric layer deforms in a process for manufacturing the piezoelectric device, it is possible to reduce or prevent characteristics from being deteriorated due to contact between the lower surface of the piezoelectric layer and the bottom surface of the space portion.

According to an example embodiment of the present invention, the support is located on the first direction side of the space portion. Accordingly, the piezoelectric layer is supported by the support. Thus, it is possible to further reduce or prevent the piezoelectric layer from being damaged.

According to an example embodiment of the present invention, the at least one functional electrode includes the upper electrode provided on the upper surface of the piezoelectric layer, and the lower electrode provided on the lower surface of the piezoelectric layer, the lower electrode at least partially facing the upper electrode. Also in this case, it is possible to reduce or prevent the piezoelectric layer from being damaged.

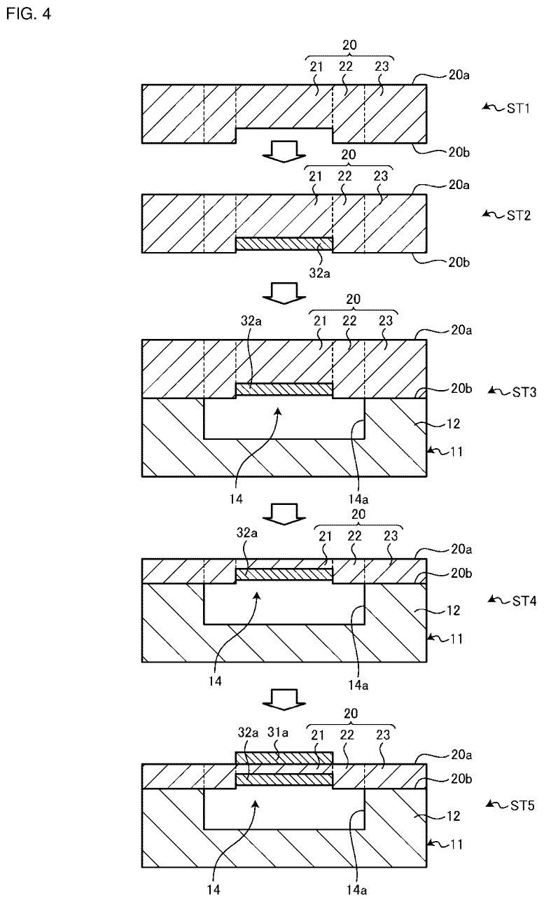

Next, an example of a method for manufacturing the piezoelectric device according to the present example embodiment will be described. FIG. 4 is an explanatory diagram for describing a method for manufacturing the piezoelectric device according to Example Embodiment 1.

As illustrated in FIG. 4, the thickness of the first portion 21 of the piezoelectric layer 20 is reduced (step ST1). In the step ST1, for example, a resist mask is patterned by lithography on the portion of the lower surface 20b of the piezoelectric layer 20 other than the first portion 21, and a portion of the first portion 21 is removed by, for example, reactive ion etching (RIE) (step ST1). Accordingly, the thickness of the second portion 22 becomes larger than the thickness of the first portion 21. Thus, it is possible to reduce or prevent the piezoelectric layer 20 from being damaged.

Subsequently, the lower electrode 32 is formed on the portion of the lower surface 20b of the first portion 21 of the piezoelectric layer 20 (step ST2). The lower electrode 32 is formed by, for example, a vapor deposition lift-off process. That is, in the step ST2, a metal film is deposited in a state in which the resist is formed in the step ST1, and the resist is then removed to form the metal film as the lower electrode 32.

Subsequently, the support substrate 12 including the space portion 14 in one surface thereof is prepared, and the support substrate 12 and the lower surface 20b of the piezoelectric layer 20 are connected to each other. Thus, the support substrate 12 and the piezoelectric layer 20 are attached to each other (step ST3). The support substrate 12 is connected to the piezoelectric layer 20 by, for example, direct bonding, plasma activated bonding, or atomic diffusion bonding. In addition, for example, a resist mask is patterned by lithography on the portion other than the first portion 21, and a portion of the support substrate 12 is removed by, for example, RIE to form the space portion 14.

Subsequently, the upper surface 20a of the piezoelectric layer 20 is ground and polished to thin the piezoelectric layer 20 (step ST4). The upper surface 20a of the piezoelectric layer 20 is polished by, for example, mechanical polishing or chemical-mechanical polishing (CMP). The piezoelectric layer 20 is formed so as to have a thickness of, for example, about 1 μm or less. In the step ST3, instead of polishing, for example, the piezoelectric layer 20 may be thinned such that a damaged layer is formed in the piezoelectric layer 20 by ion implantation and an upper layer of the formed damaged layer is removed.

Subsequently, the upper electrode 31 is formed on the upper surface 20a of the piezoelectric layer 20 (step ST5). Similarly to the lower electrode 32 described above, the upper electrode 31 is formed by, for example, a vapor deposition lift-off process. That is, in the step ST5, a resist is patterned by, for example, photolithography on the upper surface 20a of the piezoelectric layer 20. Subsequently, the resist is removed to form the metal film, as the upper electrode 31, on the part where the resist is not removed.

The piezoelectric device 10 according to the present example embodiment can be manufactured by the above steps. The steps in FIG. 4 are merely schematically illustrated and can be changed as appropriate.

As described above, the example of the method for manufacturing the piezoelectric device according to Example Embodiment 1 includes a step of grinding and thinning a portion of the piezoelectric layer with a thickness in the first direction (step ST1), a step of connecting the support to the lower surface being one surface of the piezoelectric layer in the first direction (step ST3), and a step of forming at least one functional electrode on at least one of the upper surface being the other surface of the piezoelectric layer in the first direction and the lower surface (step ST2 and/or ST5). The piezoelectric layer or the support includes the space portion in a region overlapping at least a portion of the at least one functional electrode. When the region of the piezoelectric layer that overlaps the space portion and the at least one functional electrode in plan view in the first direction is the first portion and the region of the piezoelectric layer that overlaps the space portion in plan view in the first direction and that does not overlap the at least one functional electrode in plan view in the first direction is the second portion, the maximum thickness of the second portion is larger than the minimum thickness of the first portion. Thus, it is possible to reduce or prevent a strain from being caused on the piezoelectric layer at the boundary between the region overlapping the at least one functional electrode in plan view in the first direction and the region not overlapping the at least one functional electrode in plan view in the first direction and to thus reduce or prevent the piezoelectric layer from being damaged.

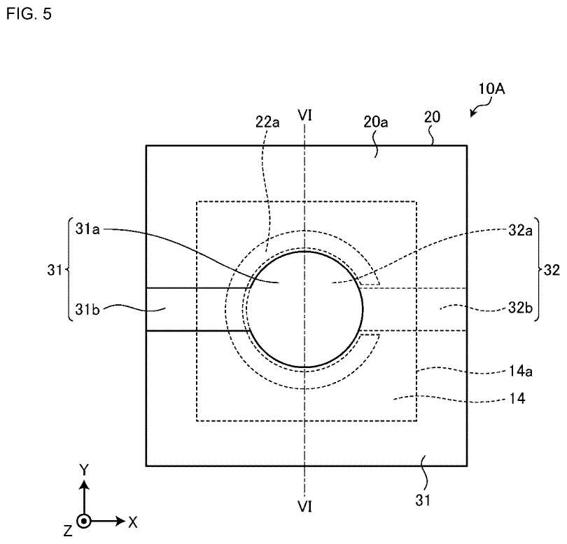

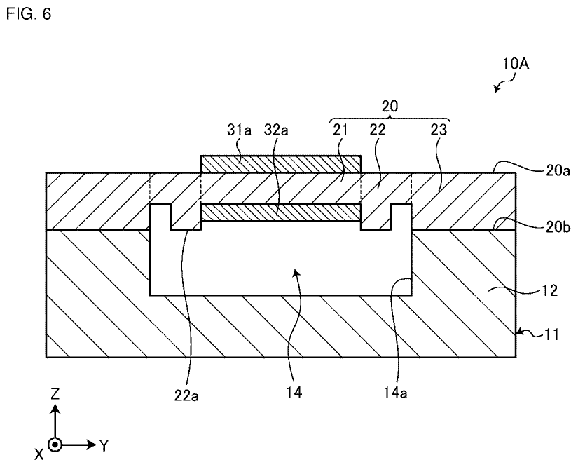

FIG. 5 is a plan view illustrating a piezoelectric device according to Modification 1 of Example Embodiment 1 of the present invention. FIG. 6 is a schematic sectional view taken along line VI-VI in FIG. 5. As illustrated in FIG. 5, a piezoelectric device 10A according to Modification 1 differs from the piezoelectric device 10 in that the thickness of a portion of the second portion 22 of the piezoelectric layer 20 is larger than the thickness of the first portion of the piezoelectric layer 20.

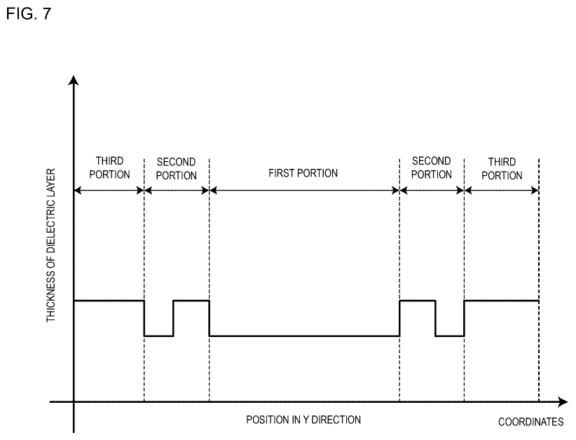

FIG. 7 is a diagram illustrating the distribution of the thickness of a piezoelectric layer according to Modification 1. More specifically, FIG. 7 is a diagram illustrating the distribution of the thickness of the piezoelectric layer 20 at each corresponding position in the Y direction in the section of FIG. 6. In Modification 1, in the second portion 22 of the piezoelectric layer 20, the lower surface 20b includes a projection 22a. Accordingly, the thickness of a portion of the second portion 22 is larger than the thickness of the first portion 21. Thus, it is possible to reduce or prevent a strain from being caused on the piezoelectric layer 20 at the boundary between the first portion 21 and the second portion 22 and to thus reduce or prevent the piezoelectric layer 20 from being damaged.

In Modification 1 in FIG. 5, the shape of the projection 22a is a ring shape not including a portion overlapping the lower electrode 32 in plan view in the Z direction, and an inner side surface of the ring is in contact with a side surface of the lower electrode 32. The position and the shape of the projection 22a are merely examples and are not limited thereto. In addition, in Modification 1 in FIG. 6, the thickness of the second portion 22 at the projection 22a is equal or substantially equal to the thickness of the third portion 23, and the thickness of the second portion 22 at the portion other than the projection 22a is equal or substantially equal to the thickness of the first portion. However, this is merely an example, and the configuration is not limited thereto.

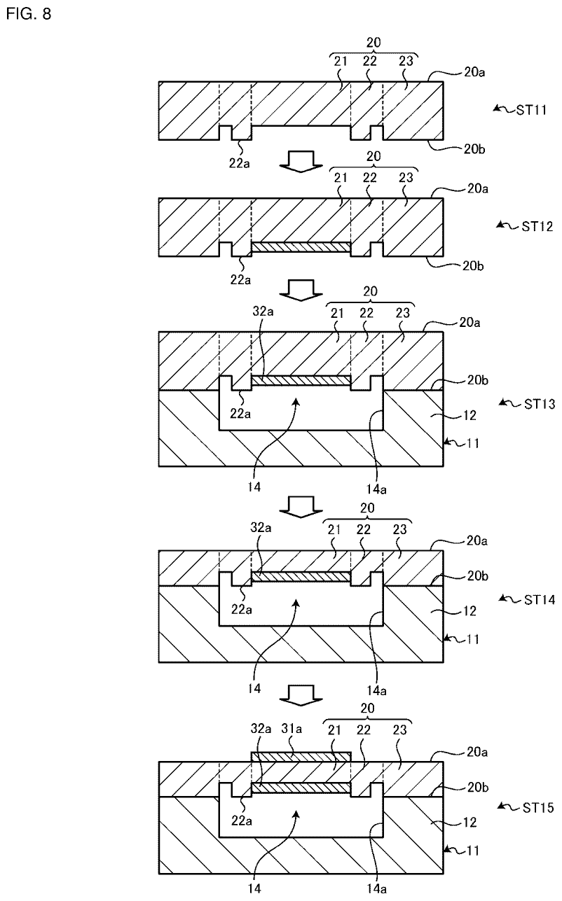

Next, an example of a method for manufacturing the piezoelectric device according to Modification 1 will be described. FIG. 8 is an explanatory diagram for describing an example of a method for manufacturing the piezoelectric device according to Modification 1. In the description of the manufacturing method illustrated in FIG. 8, matters overlapping those of the manufacturing method illustrated in FIG. 4 described above are omitted.

As illustrated in FIG. 8, the thickness of the first portion 21 of the piezoelectric layer 20 and the thickness of a portion of the second portion 22 of the piezoelectric layer 20 are reduced (step ST11). In the step ST11, for example, a resist mask is patterned by, for example, lithography on the portion of the lower surface 20b of the piezoelectric layer 20 of the projection 22a of the second portion 22 and the third portion 23, and a portion of the first portion 21 and a portion of the second portion 22 other than the projection 22a are removed by, for example, RIE (step ST11). Thus, a portion of the second portion 22 is formed so as to be thicker than the first portion 21. Accordingly, it is possible to reduce or prevent the piezoelectric layer 20 from being damaged. The resist is removed after the step ST11.

Thereafter, similarly to the steps ST2 to ST5 in FIG. 4, the lower electrode 32 is formed on the portion of the lower surface 20b of the first portion 21 of the piezoelectric layer 20 (step ST12), the support substrate 12 including the space portion 14 in one surface thereof and the lower surface 20b of the piezoelectric layer 20 are connected and attached to each other (step ST13), the upper surface 20a of the piezoelectric layer 20 is ground and polished to thin the piezoelectric layer 20 (step ST14), and the upper electrode 31 is formed on the upper surface 20a of the piezoelectric layer 20 (step ST15).

The piezoelectric device 10A according to the present modification is manufactured by using the above steps. The steps in FIG. 8 are merely schematically illustrated and can be changed as appropriate.

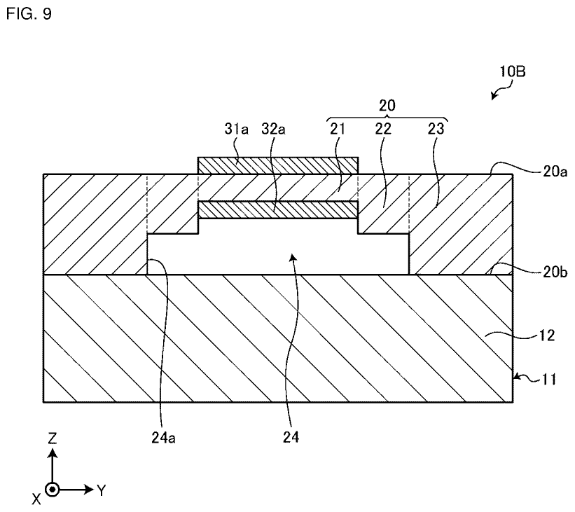

FIG. 9 is a schematic sectional view illustrating a piezoelectric device according to Example Embodiment 2 of the present invention. As illustrated in FIG. 9, a piezoelectric device 10B according to Example Embodiment 2 differs from the piezoelectric device according to Example Embodiment 1 in that the piezoelectric layer 20 includes a space portion 24.

In Example Embodiment 2, the piezoelectric layer 20 includes the space portion 24. In Example Embodiment 2, as illustrated in FIG. 9, the space portion 24 is a space in the recess provided in the lower surface 20b of the piezoelectric layer 20. The space portion 24 is provided so as to overlap the excitation region in plan view in the Z direction. Thus, a bulk wave is reflected by the space portion 24.

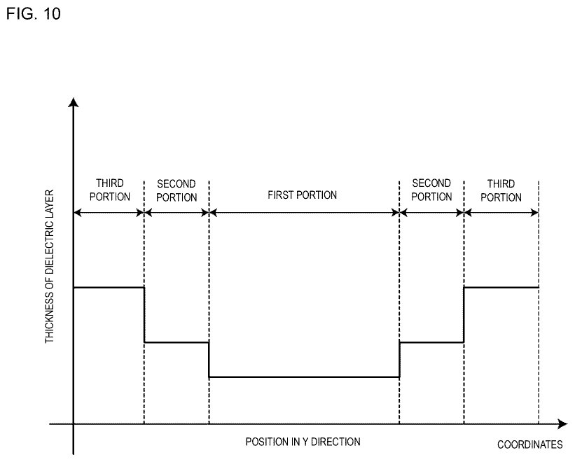

FIG. 10 is a diagram illustrating the distribution of the thickness of a piezoelectric layer according to Example Embodiment 2. More specifically, FIG. 10 is a diagram illustrating the distribution of the thickness of the piezoelectric layer 20 at each corresponding position in the Y direction in the section of FIG. 9. In Example Embodiment 2, the thickness of the second portion 22 of the piezoelectric layer 20 is larger than the thickness of the first portion 21 of the piezoelectric layer 20. Thus, it is possible to reduce or prevent a strain from being caused on the piezoelectric layer 20 at the boundary between the first portion 21 and the second portion 22 and to thus reduce or prevent the piezoelectric layer 20 from being damaged.

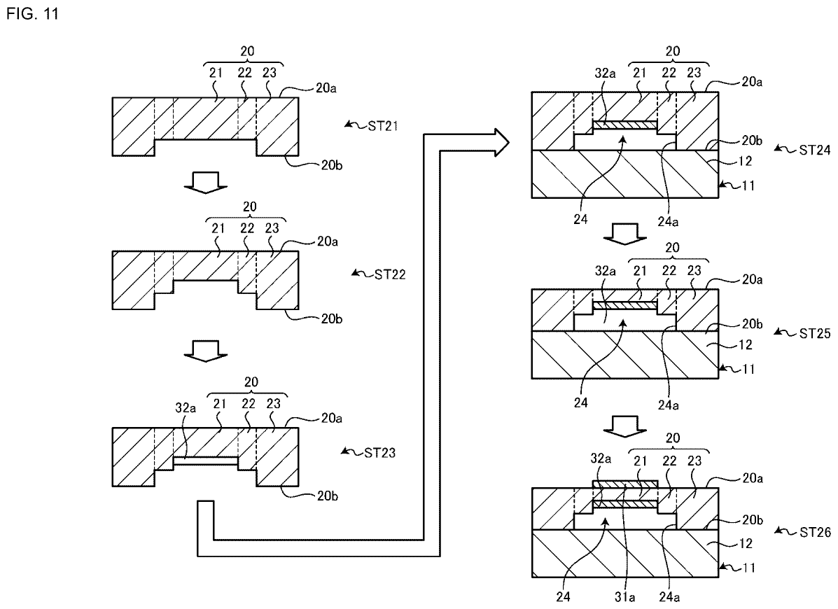

Next, an example of a method for manufacturing the piezoelectric device according to the present example embodiment will be described. FIG. 11 is an explanatory diagram for describing a method for manufacturing the piezoelectric device according to Example Embodiment 2. In the description of the manufacturing method illustrated in FIG. 11, matters overlapping those of the manufacturing method illustrated in FIG. 4 described above are omitted.

As illustrated in FIG. 11, the thickness of each of the first portion 21 and the second portion 22 of the piezoelectric layer 20 is reduced (step ST21). In the step ST21, for example, a resist mask is patterned by lithography on the part of the lower surface 20b of the piezoelectric layer 20 of the third portion 23, and a portion of each of the first portion 21 and the second portion 22 is removed by RIE (step ST21). Thus, the space portion 24 is formed. The resist is removed after the step ST21.

Subsequently, the thickness of the first portion 21 of the piezoelectric layer 20 is further reduced (step ST22). In the step ST22, for example, a resist mask is patterned by lithography on the portion of the lower surface 20b of the piezoelectric layer 20 of the second portion 22 and the third portion 23, and a portion of the first portion 21 is removed by RIE (step ST22). Accordingly, the thickness of the second portion 22 becomes larger than the thickness of the first portion 21. Thus, it is possible to reduce or prevent the piezoelectric layer 20 from being damaged.

Subsequently, similarly to the step ST2 in FIG. 4, the lower electrode 32 is formed on the lower surface 20b of the piezoelectric layer 20 (step ST23).

Subsequently, the support substrate 12 is prepared, and the support substrate 12 and the lower surface 20b of the piezoelectric layer 20 are connected to each other. Thus, the support substrate 12 and the piezoelectric layer 20 are attached to each other (step ST24). The support substrate 12 is connected to the piezoelectric layer 20 by, for example, direct bonding, plasma activated bonding, or atomic diffusion bonding.

Then, similarly to the steps ST4 and ST5 in FIG. 4, the upper surface 20a of the piezoelectric layer 20 is ground and polished to thin the piezoelectric layer 20 (step ST25), and the upper electrode 31 is formed on the upper surface 20a of the piezoelectric layer 20 (step ST26).

The piezoelectric device 10B according to Example Embodiment 2 is manufactured by the above steps. The steps in FIG. 11 are merely schematically illustrated and can be changed as appropriate.

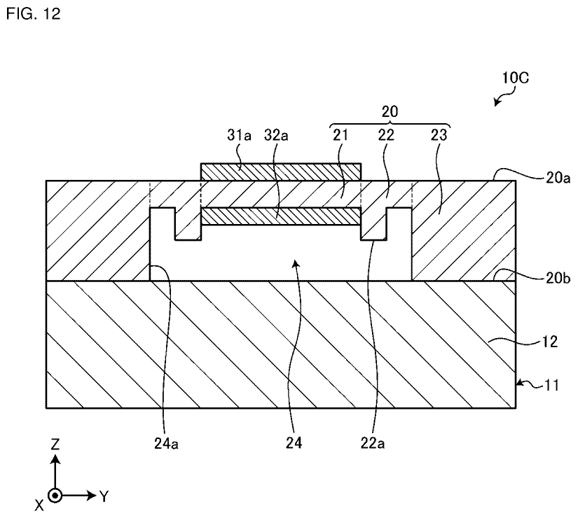

FIG. 12 is a schematic sectional view illustrating a piezoelectric device according to Modification 2 of Example Embodiment 2 of the present invention. As illustrated in FIG. 12, a piezoelectric device 10C according to Modification 2 differs from the piezoelectric device according to Example Embodiment 2 in that the thickness of a portion of the second portion 22 of the piezoelectric layer 20 is larger than the thickness of the first portion of the piezoelectric layer 20.

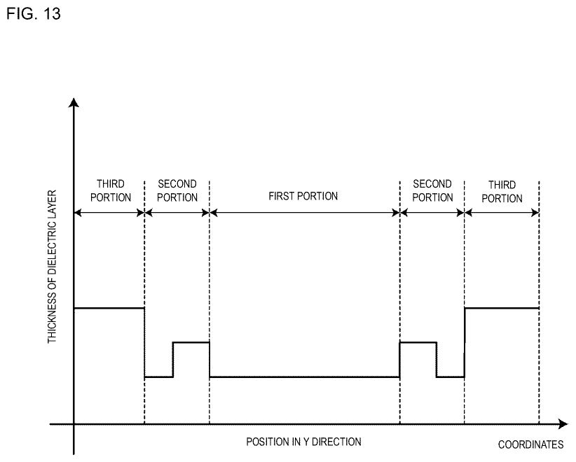

FIG. 13 is a diagram illustrating the distribution of the thickness of a piezoelectric layer according to Modification 2 of Example Embodiment 2. More specifically, FIG. 13 is a diagram illustrating the distribution of the thickness of the piezoelectric layer 20 at each corresponding position in the Y direction in the section of FIG. 12. In Modification 2, in the second portion 22 of the piezoelectric layer 20, the lower surface 20b includes the projection 22a. Accordingly, the thickness of the projection 22a of the second portion 22 is larger than the thickness of the first portion 21. Thus, it is possible to reduce or prevent a strain from being caused on the piezoelectric layer 20 at the boundary between the first portion 21 and the second portion 22 and to thus reduce or prevent the piezoelectric layer 20 from being damaged.

The shape of the projection 22a in plan view in the Z direction is not particularly limited and is, for example, a ring shape not including the portion overlapping the upper electrode 31 and the lower electrode 32 similarly to Modification 1 of Example Embodiment 1. In addition, in Modification 2 in FIG. 12, the thickness of the second portion 22 at the projection 22a is smaller than the thickness of the third portion 23, and the thickness of the second portion 22 at the portion other than the projection 22a is equal or substantially equal to the thickness of the first portion 21. However, this is merely an example, and the configuration is not limited thereto.

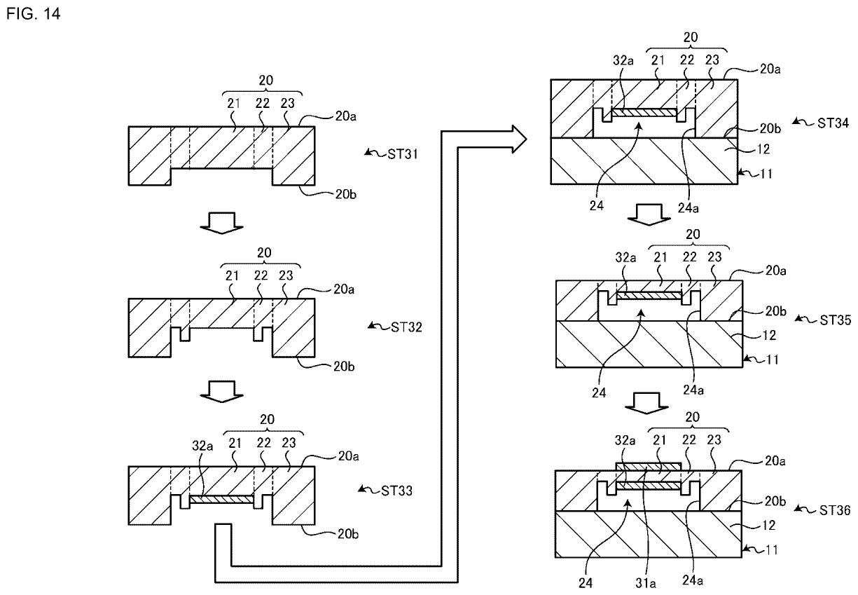

Next, an example of a method for manufacturing the piezoelectric device according to Modification 2 will be described. FIG. 14 is an explanatory diagram for describing a method for manufacturing the piezoelectric device according to Modification 2 of Example Embodiment 2. In the description of the manufacturing method illustrated in FIG. 14, matters overlapping those of the manufacturing method illustrated in FIG. 11 described above are omitted.

As illustrated in FIG. 14, the thickness of each of the first portion 21 and the second portion 22 of the piezoelectric layer 20 is reduced (step ST31). In the step ST31, for example, a resist mask is patterned by lithography on the portion of the lower surface 20b of the piezoelectric layer 20 of the third portion 23, and a portion of each of the first portion 21 and the second portion 22 is removed by RIE (step ST31). Thus, the space portion 24 is formed. The resist is removed after the step ST31.

Subsequently, the thickness of the first portion 21 of the piezoelectric layer 20 and the thickness of a portion of the second portion 22 of the piezoelectric layer 20 are reduced (step ST32). In the step ST32, for example, a resist mask is patterned by lithography on the portion of the lower surface 20b of the piezoelectric layer 20 of the projection 22a of the second portion 22 and the third portion 23, and a portion of the first portion 21 and a portion of the second portion 22 other than the projection 22a are removed by RIE (step ST32). Thus, a portion of the second portion 22 is formed so as to be thicker than the first portion 21. Accordingly, it is possible to reduce or prevent the piezoelectric layer 20 from being damaged. The resist is removed after the step ST32.

Thereafter, similarly to the steps ST23 to ST26 in FIG. 11, the lower electrode 32 is formed on the portion of the lower surface 20b of the first portion 21 of the piezoelectric layer 20 (step ST33), the support substrate 12 and the lower surface 20b of the piezoelectric layer 20 are connected and attached to each other (step ST34), the upper surface 20a of the piezoelectric layer 20 is ground and polished to thin the piezoelectric layer 20 (step ST35), and the upper electrode 31 is formed on the upper surface 20a of the piezoelectric layer 20 (step ST36).

The piezoelectric device 10C according to the present modification is manufactured by the above steps. The steps in FIG. 14 are merely schematically illustrated and can be changed as appropriate.

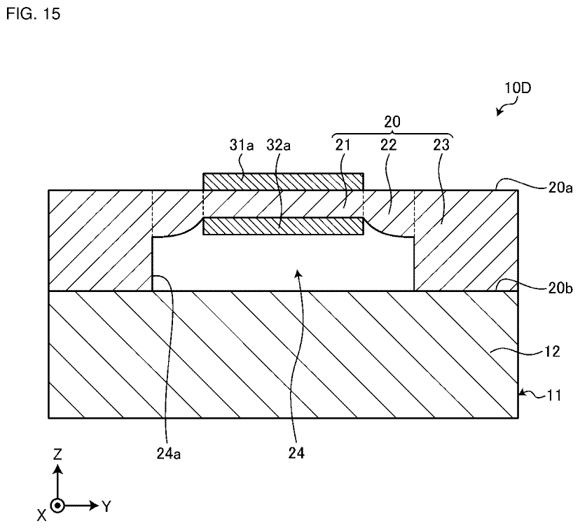

FIG. 15 is a schematic sectional view illustrating a piezoelectric device according to Modification 3 of Example Embodiment 2 of the present invention. As illustrated in FIG. 15, a piezoelectric device 10D according to Modification 3 differs from the piezoelectric device according to Example Embodiment 2 in that the thickness of the second portion 22 of the piezoelectric layer 20 on the boundary 24a side is larger than the thickness of the second portion 22 of the piezoelectric layer 20 on the first portion 21 side.

In Modification 3, in the second portion 22 of the piezoelectric layer 20, the lower surface 20b is convex. Accordingly, the thickness of the second portion 22 of the piezoelectric layer 20 on the third portion 23 side is larger than the thickness of the second portion 22 of the piezoelectric layer 20 on the first portion 21 side. That is, in Modification 3, the average thickness of the second portion 22 at the boundary 24a between a region overlapping the space portion 24 and a region not overlapping the space portion 24 is larger than the average thickness of the second portion 22 at the boundary between a region overlapping the functional electrodes and a region not overlapping the functional electrodes. Thus, it is possible to reduce or prevent a strain from being caused on the piezoelectric layer 20 at the boundary 24a and the boundary between the first portion 21 and the second portion 22 and to thus reduce or prevent the piezoelectric layer 20 from being damaged.

Here, the piezoelectric device 10D according to Modification 3 can be manufactured by using a method the same as or similar to that of the piezoelectric device 10C according to Modification 2.

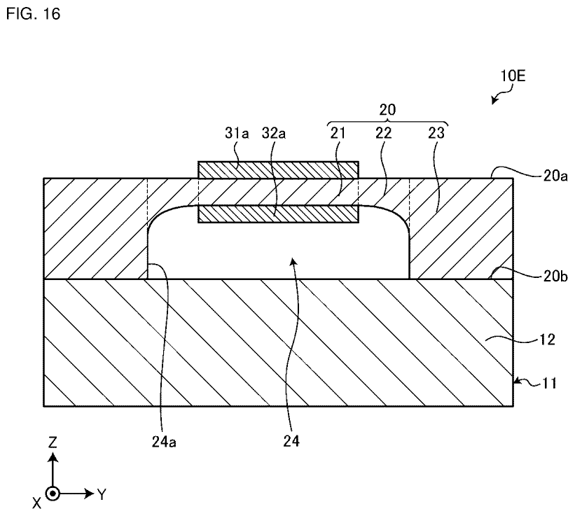

FIG. 16 is a schematic sectional view illustrating a piezoelectric device according to Modification 4 of Example Embodiment 2 of the present invention. As illustrated in FIG. 16, a piezoelectric device 10E according to Modification 4 differs from the piezoelectric device according to Example Embodiment 2 in that the thickness of the second portion 22 of the piezoelectric layer 20 on the boundary 24a side is larger than the thickness of the second portion 22 of the piezoelectric layer 20 on the first portion 21 side.

In Modification 4, in the second portion 22 of the piezoelectric layer 20, the lower surface 20b is concave. Accordingly, the thickness of the second portion 22 of the piezoelectric layer 20 on the third portion 23 side is larger than the thickness of the second portion 22 of the piezoelectric layer 20 on the first portion 21 side. That is, in Modification 4, the average thickness of the second portion 22 at the boundary 24a between a region overlapping the space portion 24 and a region not overlapping the space portion 24 is larger than the average thickness of the second portion 22 at the boundary between a region overlapping the functional electrodes and a region not overlapping the functional electrodes. Thus, it is possible to reduce or prevent a strain from being caused on the piezoelectric layer 20 at the boundary 24a and the boundary between the first portion 21 and the second portion 22 and to thus reduce or prevent the piezoelectric layer 20 from being damaged.

Here, the piezoelectric device 10E according to Modification 4 can be manufactured by a method the same as or similar to that of the piezoelectric device 10C according to Modification 2.

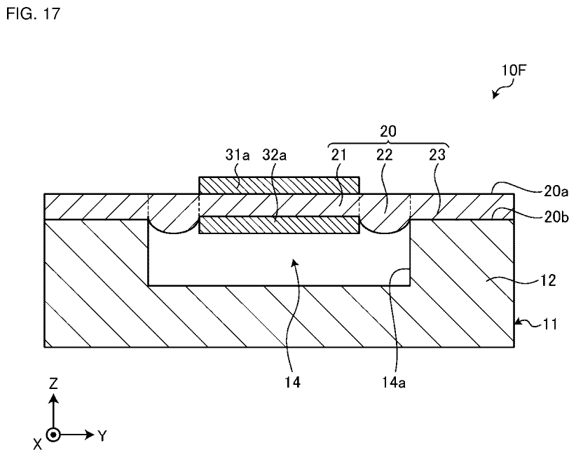

FIG. 17 is a schematic sectional view illustrating a piezoelectric device according to Example Embodiment 3 of the present invention. As illustrated in FIG. 17, a piezoelectric device 10F according to Example Embodiment 3 differs from the piezoelectric device according to Example Embodiment 1 in that the thickness of the second portion 22 is larger than the thickness of the third portion 23.

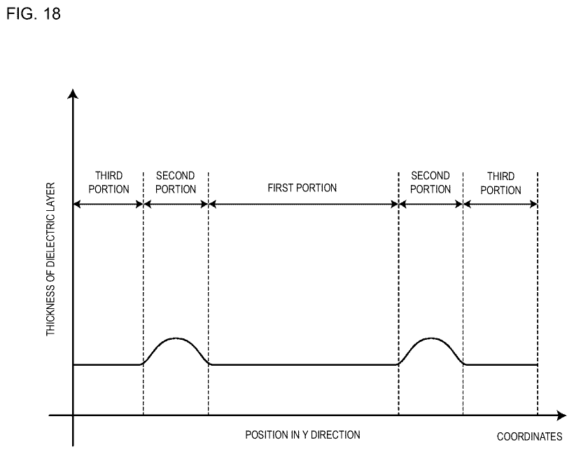

FIG. 18 is a diagram illustrating the distribution of the thickness of a piezoelectric layer according to Example Embodiment 3. More specifically, FIG. 18 is a diagram illustrating the distribution of the thickness of the piezoelectric layer 20 at each corresponding position in the Y direction in the section of FIG. 17. In Example Embodiment 3, the maximum thickness of the second portion 22 of the piezoelectric layer 20 is larger than the thickness of each of the first portion 21 and the third portion 23 of the piezoelectric layer 20. Thus, it is possible to reduce or prevent a strain from being caused on the piezoelectric layer 20 at the boundary between the first portion 21 and the second portion 22 and to thus reduce or prevent the piezoelectric layer 20 from being damaged.

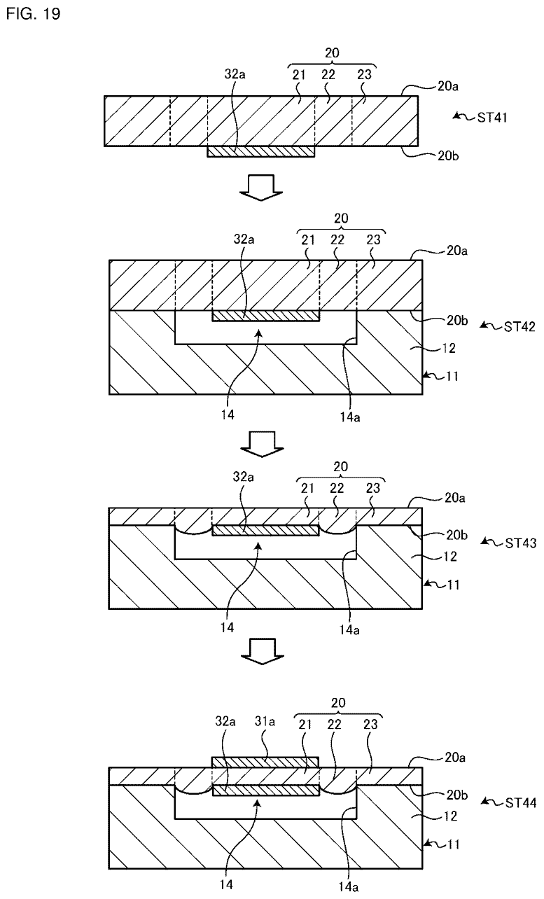

Next, an example of a method for manufacturing the piezoelectric device according to the present example embodiment will be described. FIG. 19 is an explanatory diagram for describing an example of a method for manufacturing the piezoelectric device according to Example Embodiment 3. In the description of the method for manufacturing the piezoelectric device according to Example Embodiment 3, matters overlapping those of the manufacturing method illustrated in FIG. 4 described above are omitted.

Similarly to the steps ST2 and ST3 in FIG. 4, the lower electrode 32 is formed on the lower surface 20b of the piezoelectric layer 20 (step ST41), and the support substrate 12 and the lower surface 20b of the piezoelectric layer 20 are connected and attached to each other (step ST42). In Example Embodiment 3, the steps ST41 and ST42 are performed without a reduction in the thickness of the first portion 21 of the piezoelectric layer 20. That is, in the steps before a step ST43, the first portion 21, the second portion 22, and the third portion 23 of the piezoelectric layer 20 are uniform in thickness, and the lower surface 20b is a flat surface.

Then, similarly to the step ST4 in FIG. 4, the upper surface 20a of the piezoelectric layer 20 is ground and polished to thin the piezoelectric layer 20. The upper surface 20a of the piezoelectric layer 20 is polished by, for example, mechanical polishing. The piezoelectric layer 20 is formed so as to have a thickness of, for example, about 1 μm or less (step ST43).

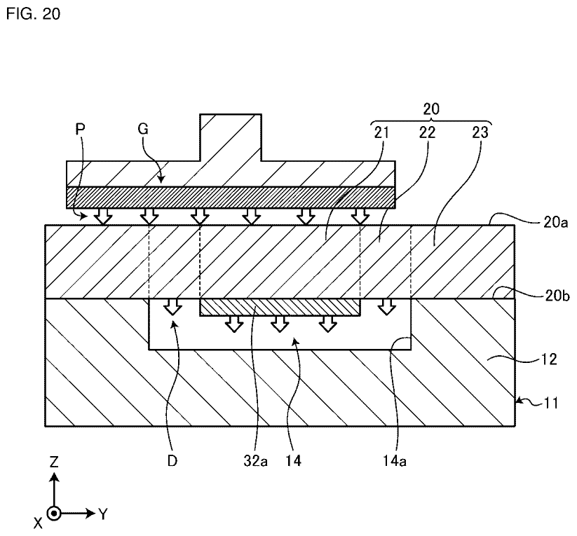

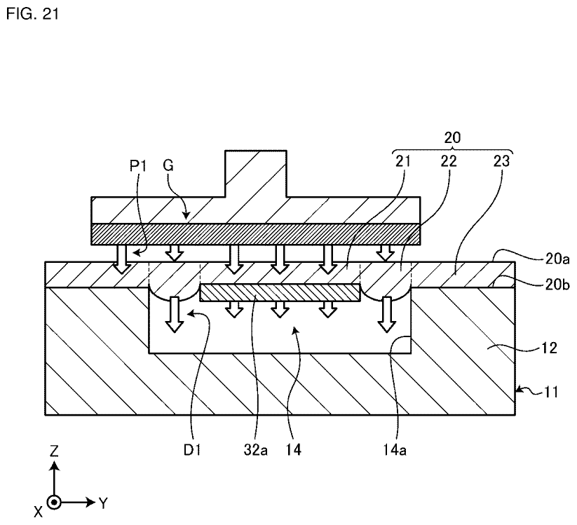

FIGS. 20 and 21 are diagrams for describing a step of thinning the piezoelectric layer according to Example Embodiment 3. In the step ST43, the upper surface 20a of the piezoelectric layer 20 is polished by, for example, moving a grinder G along the XY plane while the grinder G is rotated and scanning the upper surface 20a of the piezoelectric layer 20. In this case, a pressure P is applied to the piezoelectric layer 20 in a direction from the upper surface toward the lower surface due to the pressure difference between the inside and the outside of the space portion 14 and pressing of the grinder G. As illustrated in FIG. 20, when the piezoelectric layer 20 is sufficiently thick, the piezoelectric layer 20 is unlikely to bend, the displacement D thereof due to the pressure P is thus small, and the difference in displacement D between positions therein is also small. As a result, the piezoelectric layer 20 is uniformly polished. On the other hand, as illustrated in FIG. 21, when the piezoelectric layer 20 becomes thin, the piezoelectric layer 20 is likely to bend, the displacement D1 of the second portion 22, which is not fixed by the lower electrode 32, is locally large. Thus, the second portion 22 projects into the space portion 14. Accordingly, the amount of polishing of the second portion 22 is reduced. As a result, the thickness of the second portion 22 of the piezoelectric layer 20 is larger than the thickness of each of the first portion 21 and the third portion 23 of the piezoelectric layer 20. Thus, it is possible to reduce or prevent the piezoelectric layer 20 from being damaged.

Then, similarly to the step ST5 in FIG. 4, the upper electrode 31 is formed on the upper surface 20a of the piezoelectric layer 20 (step ST44).

The piezoelectric device 10F according to Example Embodiment 3 is manufactured by, for example, using the above steps. The steps in FIGS. 19 to 21 are merely schematically illustrated and can be changed as appropriate.

As described above, the example of the method for manufacturing the piezoelectric device according to Example Embodiment 3 includes a step of connecting the support to the lower surface being one surface of the piezoelectric layer, in the first direction, including a thickness in the first direction (step ST42), a step of forming a functional electrode on the lower surface (step ST41), and a step of grinding the upper surface being the other surface of the piezoelectric layer in the first direction and reducing the thickness of the piezoelectric layer (step ST43). The support includes the space portion in a region overlapping at least a portion of the functional electrode. When the region of the piezoelectric layer that overlaps the space portion and the functional electrode in plan view in the first direction is the first portion and the region of the piezoelectric layer that overlaps the space portion in plan view in the first direction and that does not overlap the functional electrode in plan view in the first direction is the second portion, the average thickness of the second portion is equal or substantially equal to the average thickness of the first portion before the step of reducing the thickness of the piezoelectric layer (step ST43), and the maximum thickness of the second portion is larger than the minimum thickness of the first portion after the step of reducing the thickness of the piezoelectric layer (step ST43). Thus, it is possible to reduce or prevent a strain from being caused on the piezoelectric layer at the boundary between the region overlapping the functional electrode in plan view in the first direction and the region not overlapping the functional electrode in plan view in the first direction and to thus reduce or prevent the piezoelectric layer from being damaged.

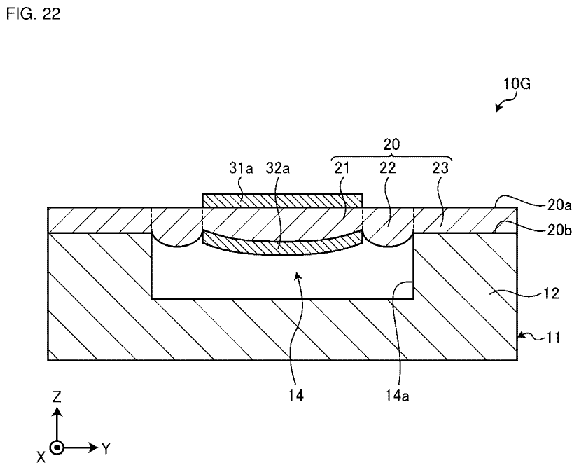

FIG. 22 is a schematic sectional view illustrating a piezoelectric device according to Modification 5 of Example Embodiment 3 of the present invention. As illustrated in FIG. 22, a piezoelectric device 10G according to Modification 5 differs from the piezoelectric device according to Example Embodiment 3 in that the thickness of the first portion 21 is not uniform.

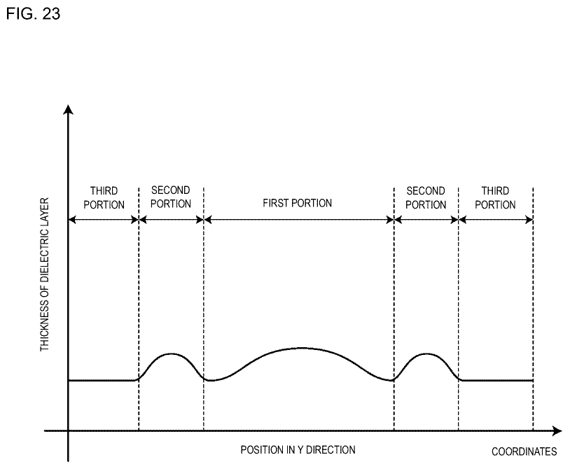

FIG. 23 is a diagram illustrating the distribution of the thickness of a piezoelectric layer according to Modification 5 of Example Embodiment 3. More specifically, FIG. 23 is a diagram illustrating the distribution of the thickness of the piezoelectric layer 20 at each corresponding position in the Y direction in the section of FIG. 22. As illustrated in FIGS. 22 and 23, the thickness of the first portion 21 at each end (end portion) thereof on the second portion 22 side is smaller, and the thickness of the first portion 21 at the inside of each end on the second portion 22 side (center) is larger. In Modification 5, the maximum thickness of the second portion 22 of the piezoelectric layer 20 is larger than the minimum thickness of the first portion 21 of the piezoelectric layer 20 and the thickness of the third portion 23 of the piezoelectric layer 20. Thus, it is possible to reduce or prevent a strain from being caused on the piezoelectric layer 20 at the boundary between the first portion 21 and the second portion 22 and to thus reduce or prevent the piezoelectric layer 20 from being damaged.

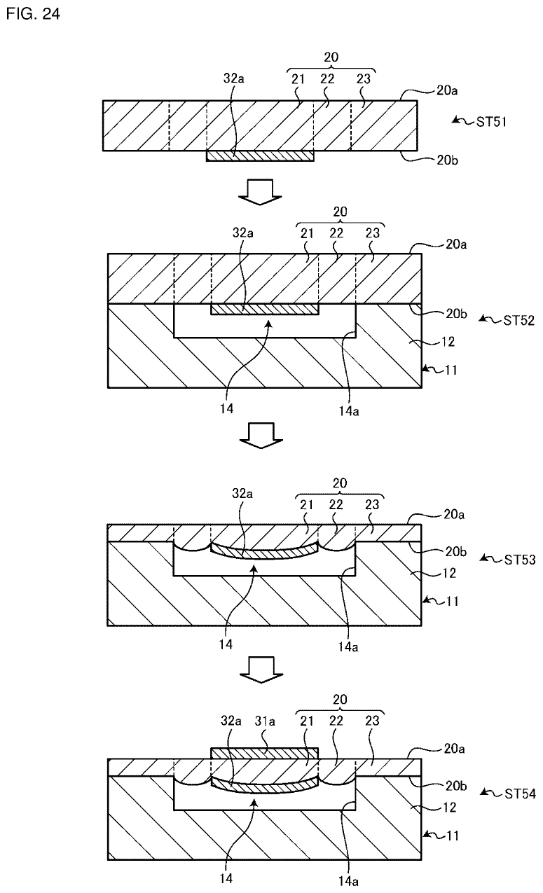

Next, an example of a method for manufacturing the piezoelectric device according to the present modification will be described. FIG. 24 is an explanatory diagram for describing an example of a method for manufacturing the piezoelectric device according to Modification 5 of Example Embodiment 3. In the description of the method for manufacturing the piezoelectric device according to Modification 5, matters overlapping those of the manufacturing methods illustrated in FIGS. 4 and 19 described above are omitted.

Similarly to the steps ST2 and ST3 in FIG. 4, the lower electrode 32 is formed on the lower surface 20b of the piezoelectric layer 20 (step ST51), and the support substrate 12 and the lower surface 20b of the piezoelectric layer 20 are connected and attached to each other (step ST52).

Then, similarly to the step ST4 in FIG. 4, the upper surface 20a of the piezoelectric layer 20 is ground and polished to thin the piezoelectric layer 20 (step ST53). The upper surface 20a of the piezoelectric layer 20 is polished by, for example, mechanical polishing. The piezoelectric layer 20 is formed so as to have a thickness of, for example, about 1 μm or less.

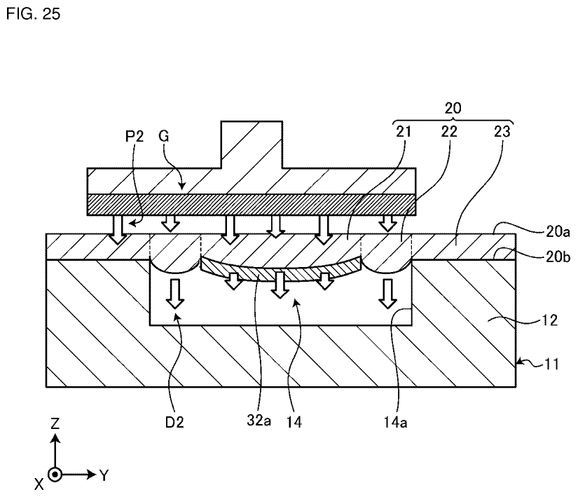

FIG. 25 is a diagram for describing a step of thinning the piezoelectric layer according to Modification 5 of Example Embodiment 3. In the step ST53, the upper surface 20a of the piezoelectric layer 20 is polished by, for example, moving the grinder G along the XY plane while the grinder G is rotated and scanning the upper surface 20a of the piezoelectric layer 20. In this case, the pressure P is applied to the piezoelectric layer 20 in the direction from the upper surface toward the lower surface due to the pressure difference between the inside and the outside of the space portion 14 and pressing of the grinder G. As illustrated in FIG. 25, when the piezoelectric layer 20 becomes thin, the piezoelectric layer 20 is likely to bend. In Modification 5, only the end portion of the first portion 21 is fixed because the lower electrode 32 is thin. Accordingly, in addition to the second portion 22, the displacement D2 of the center of the first portion 21 is locally large. Thus, the center of the first portion 21 and the second portion 22 project into the space portion 14. Accordingly, the amount of polishing of each of the center of the first portion 21 and the second portion 22 is reduced. Also in this case, the maximum thickness of the second portion 22 of the piezoelectric layer 20 is larger than the minimum thickness of the first portion 21 of the piezoelectric layer 20 and the thickness of the third portion 23 of the piezoelectric layer 20. Thus, it is possible to reduce or prevent the piezoelectric layer 20 from being damaged.

Then, similarly to the step ST5 in FIG. 4, the upper electrode 31 is formed on the upper surface 20a of the piezoelectric layer 20 (step ST54).

The piezoelectric device 10G according to Modification 5 is manufactured by using the above steps. The steps in FIG. 24 are merely schematically illustrated and can be changed as appropriate.

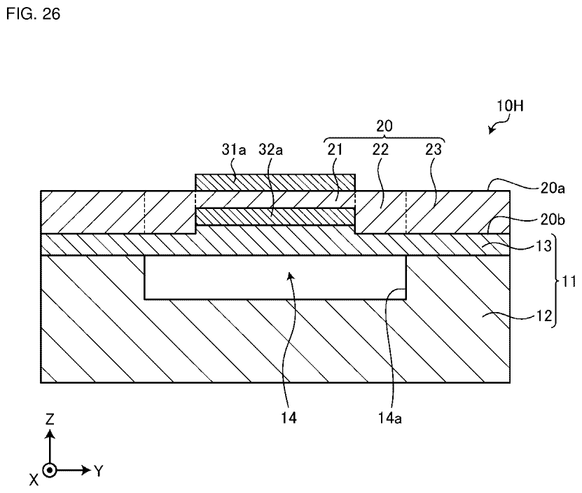

FIG. 26 is a schematic sectional view illustrating a piezoelectric device according to Example Embodiment 4 of the present invention. As illustrated in FIG. 26, a piezoelectric device 10H according to Example Embodiment 4 differs from the piezoelectric device according to Example Embodiment 1 in that the support 11 includes an intermediate layer 13.

The intermediate layer 13 is provided between the support substrate 12 and the piezoelectric layer 20. The intermediate layer 13 is made of an insulating material such, for example, as silicon oxide.

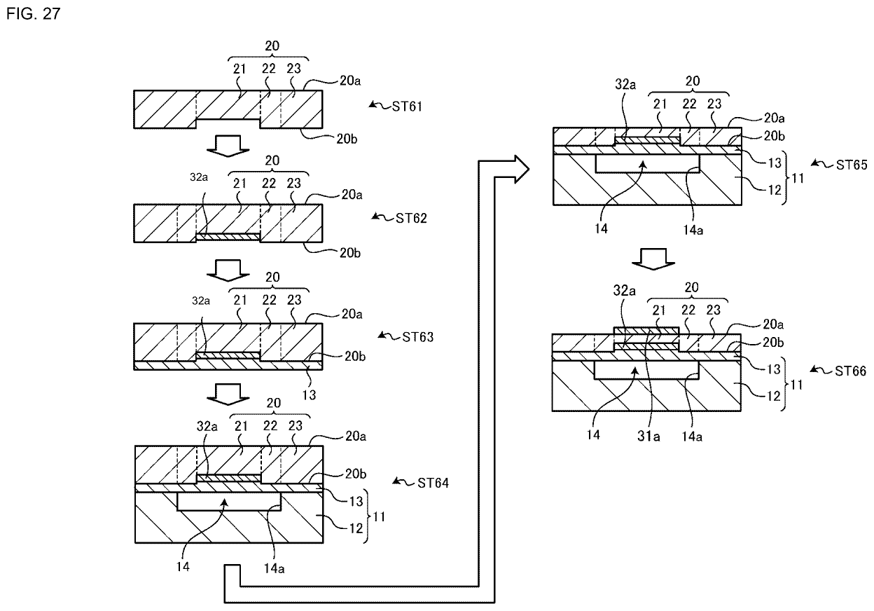

Next, an example of a method for manufacturing the piezoelectric device according to the present example embodiment will be described. FIG. 27 is an explanatory diagram for describing an example of a method for manufacturing the piezoelectric device according to Example Embodiment 4. In the description of the method for manufacturing the piezoelectric device according to Example Embodiment 4, matters overlapping those of the manufacturing method illustrated in FIG. 4 described above are omitted.

Similarly to the steps ST1 and ST2 in FIG. 4, the thickness of the first portion 21 of the piezoelectric layer 20 is reduced (step ST61). The lower electrode 32 is formed on the portion of the lower surface 20b of the first portion 21 of the piezoelectric layer 20 (step ST62).

Subsequently, the intermediate layer 13 is formed on the lower surface 20b of the piezoelectric layer 20 so as to cover the lower electrode 32 (step ST63). The intermediate layer 13 is made of a material such as, for example, silicon oxide by sputtering. An adhesion layer made of, for example, Ti or NiCr may be provided between the lower electrode 32 and the intermediate layer 13. In addition, a lower surface (surface opposite to the piezoelectric layer 20) of the intermediate layer 13 may be flattened by, for example, CMP as appropriate.

Subsequently, the support substrate 12 including the space portion 14 in one surface thereof is prepared and connected to the intermediate layer formed on the lower surface 20b of the piezoelectric layer 20. Thus, the support substrate 12 and the piezoelectric layer 20 are attached to each other (step ST64). The support substrate 12 is connected to the piezoelectric layer 20 by, for example, direct bonding, plasma activated bonding, or atomic diffusion bonding. In addition, for example, a resist mask is patterned by lithography on the portion other than the first portion 21, and a portion of the support substrate 12 is removed by RIE to form the space portion 14.

Then, similarly to the steps ST4 and ST5 in FIG. 4, the upper surface 20a of the piezoelectric layer 20 is ground and polished to thin the piezoelectric layer 20 (step ST65). The upper electrode 31 is formed on the upper surface 20a of the piezoelectric layer 20 (step ST66).

The piezoelectric device 10H according to the present example embodiment is manufactured by using the above steps. The steps in FIG. 27 are merely schematically illustrated and can be changed as appropriate.

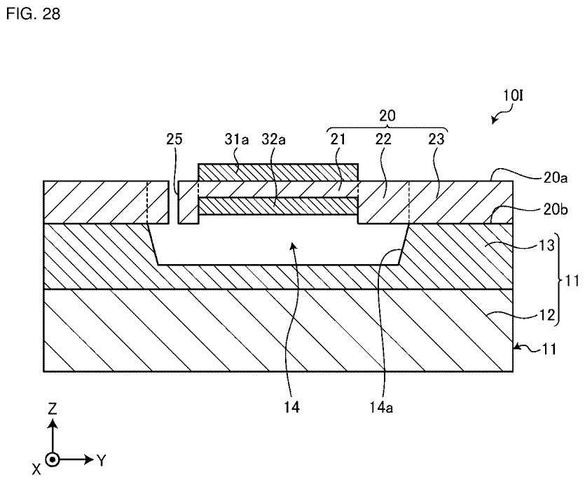

FIG. 28 is a schematic sectional view illustrating a piezoelectric device according to Example Embodiment 5 of the present invention. As illustrated in FIG. 28, a piezoelectric device 10I according to Example Embodiment 5 differs from the piezoelectric device according to Example Embodiment 1 in that the support 11 includes the intermediate layer 13 and that the intermediate layer 13 includes the space portion 14.

The intermediate layer 13 is provided between the support substrate 12 and the piezoelectric layer 20. The intermediate layer 13 is made of an insulating material such as, for example, silicon oxide. In Example Embodiment 5 in FIG. 28, the space portion 14 is a space in the recess of the intermediate layer 13 provided on the piezoelectric layer 20 side.

The piezoelectric layer 20 includes a through hole 25. The through hole 25 passes through the piezoelectric layer 20 in the Z direction and communicates with the space portion 14.

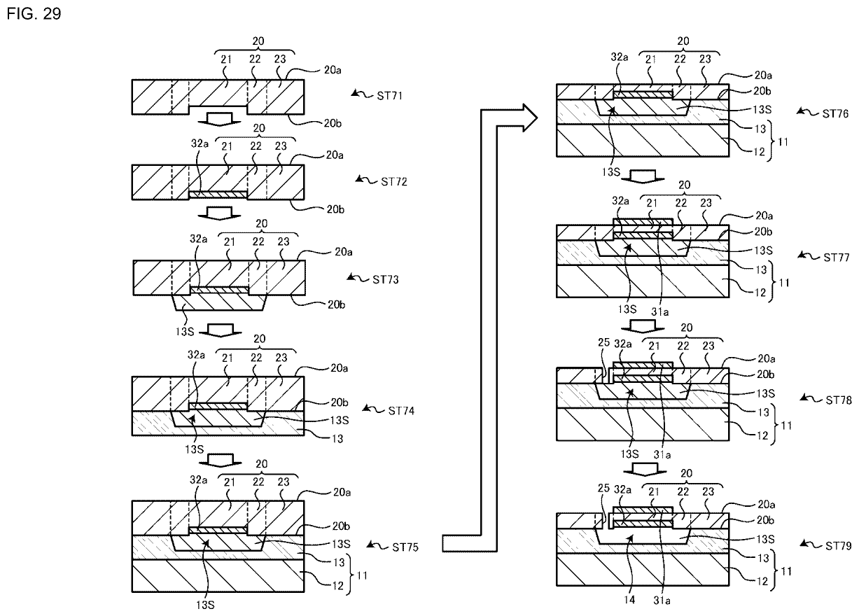

Next, an example of a method for manufacturing the piezoelectric device according to the present example embodiment will be described. FIG. 29 is an explanatory diagram for describing an example of a method for manufacturing the piezoelectric device according to Example Embodiment 5. In the description of the method for manufacturing the piezoelectric device according to Example Embodiment 5, matters overlapping those of the manufacturing method illustrated in FIG. 4 described above are omitted.

Similarly to the steps ST1 and ST2 in FIG. 4, the thickness of the first portion 21 of the piezoelectric layer 20 is reduced (step ST71). The lower electrode 32 is formed on the portion of the lower surface 20b of the first portion 21 of the piezoelectric layer 20 (step ST72).

Subsequently, a sacrificial layer 13S is formed on the lower surface 20b of the piezoelectric layer 20 (step ST73). The sacrificial layer 13S is provided in the region where the space portion 14 of the support 11 (intermediate layer 13) is to be formed. In other words, the sacrificial layer 13S is provided so as to cover the main electrode portion 32a of the lower electrode 32. The sacrificial layer 13S is made of a material such as, for example, zinc oxide (ZnO) by sputtering.

Subsequently, the intermediate layer 13 is formed on the lower surface 20b of the piezoelectric layer 20 so as to cover the lower electrode 32 and the sacrificial layer 13S (step ST74). The intermediate layer 13 is made of a material such as, for example, silicon oxide by sputtering. An adhesion layer made of, for example, Ti or NiCr may be provided between the lower electrode 32 and the intermediate layer 13. In addition, the lower surface (surface opposite to the piezoelectric layer 20) of the intermediate layer 13 may be flattened by, for example, CMP as appropriate.

Subsequently, the support substrate 12 including the space portion 14 in one surface thereof is prepared and connected to the intermediate layer formed on the lower surface 20b of the piezoelectric layer 20. Thus, the support substrate 12 and the piezoelectric layer 20 are attached to each other (step ST75). The support substrate 12 is connected to the piezoelectric layer 20 by, for example, direct bonding, plasma activated bonding, or atomic diffusion bonding.

Then, similarly to the steps ST4 and ST5 in FIG. 4, the upper surface 20a of the piezoelectric layer 20 is ground and polished to thin the piezoelectric layer 20 (step ST76). The upper electrode 31 is formed on the upper surface 20a of the piezoelectric layer 20 (step ST77).

Subsequently, the through hole 25 is formed in the piezoelectric layer 20 (step ST78). The through hole 25 is provided at a position overlapping the sacrificial layer 13S in plan view in the Z direction. The through hole 25 is provided by a method such as, for example, RIE.

Subsequently, the sacrificial layer 13S is removed to form the space portion 14 in the intermediate layer 13 (step ST79). The sacrificial layer 13S is removed by, for example, wet etching. In this case, an etchant for dissolving the sacrificial layer 13S is injected through the through hole 25.

The piezoelectric device 10I according to the present example embodiment is manufactured by using the above steps. The steps in FIG. 29 are merely schematically illustrated and can be changed as appropriate.

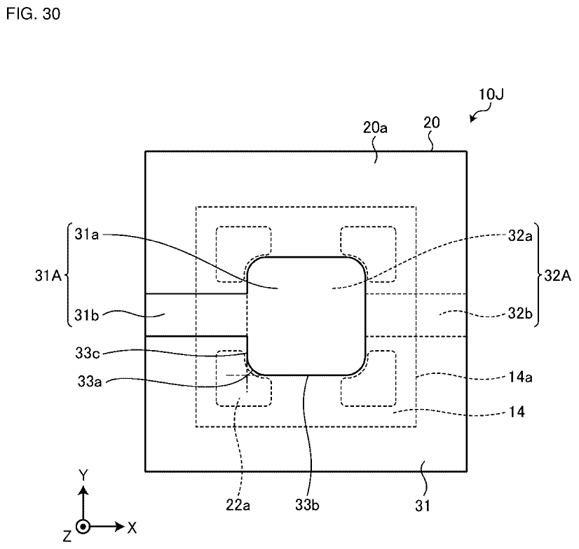

FIG. 30 is a schematic plan view illustrating a piezoelectric device according to Example Embodiment 6 of the present invention. As illustrated in FIG. 30, a piezoelectric device 10J according to Example Embodiment 6 differs from the piezoelectric device according to Example Embodiment 1 in that the main electrode portions 31a and 32a each have a rectangular or substantially rectangular shape.

As illustrated in FIG. 30, an upper electrode 31A includes the rectangular or substantially rectangular main electrode portion 31a and the extension portion 31b extending in the X direction from the main electrode portion 31a. A lower electrode 32A includes the rectangular or substantially rectangular main electrode portion 32a and the extension portion 32b extending in the X direction from the main electrode portion 32a. The rectangular or substantially rectangular main electrode portion 31a of the upper electrode 31A and the rectangular or substantially rectangular main electrode portion 32a of the lower electrode 32A overlap each other. Here, the rectangular or substantially rectangular shape means a shape including two pairs of parallel or substantially parallel sides (sides 33b and 33c) extending in respective directions crossing the Z direction and may be a shape having round corners 33a as illustrated in FIG. 30.

In Example Embodiment 6, the second portion 22 of the piezoelectric layer 20 includes the projections 22a on the lower surface 20b at respective positions adjacent to the corners 33a of the rectangular or substantially rectangular shape. Here, the corner 33a of the rectangular or substantially rectangular shape means the point that is located on the outline of the rectangular or substantially rectangular shape and that is closest to the intersection point of the sides 33b and 33c of the rectangular or substantially rectangular shape extending in respective directions crossing each other or extensions thereof (alternate long and short dash lines in FIG. 30). Accordingly, the thickness of the second portion 22 at the position adjacent to the corner 33a of the rectangular or substantially rectangular shape is larger than the thickness of the first portion 21. Thus, it is possible to reduce or prevent a strain from being caused on the piezoelectric layer 20 at the position adjacent to the corner 33a of the rectangular or substantially rectangular shape and to thus reduce or prevent the piezoelectric layer 20 from being damaged.

The piezoelectric device 10J according to Example Embodiment 6 can be manufactured by steps the same as or similar to those of the manufacturing method illustrated in FIG. 4 described above.

The functional electrodes (the upper electrode 31A and the lower electrode 32A) and the piezoelectric layer according to Example Embodiment 6 may be combined with each example embodiment and modification described above.

As described above, in the piezoelectric device according to Example Embodiment 6, the shape of the region where the upper electrode and the lower electrode overlap each other in plan view in the Z direction is the rectangular or substantially rectangular shape, in plan view in the first direction, including the two pairs of sides extending in the two respective directions crossing the first direction. The maximum thickness of the second portion at the respective positions adjacent to the corners of the rectangular or substantially rectangular shape in plan view in the first direction is larger than the minimum thickness of the first portion. Thus, it is possible to reduce or prevent a strain from being caused on the piezoelectric layer 20 at the respective positions adjacent to the corners of the rectangular or substantially rectangular shape, where such a strain is particularly likely to be caused, and to thus further reduce or prevent the piezoelectric layer from being damaged.

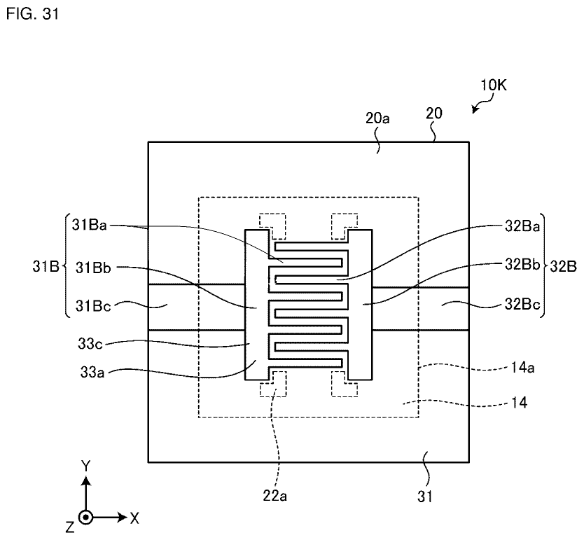

FIG. 31 is a schematic plan view illustrating a piezoelectric device according to Example Embodiment 7 of the present invention. As illustrated in FIG. 31, a piezoelectric device 10K according to Example Embodiment 7 differs from the piezoelectric device according to Example Embodiment 1 in that the functional electrodes are comb-shaped electrodes.

As illustrated in FIG. 31, a first electrode 31B includes electrode fingers 31Ba, a busbar 31Bb, which is connected to an end portion of each of the electrode fingers 31Ba in the X direction and extends in the Y direction, and an extension portion 31Bc, which extends in the X direction from the busbar 31Bb. A second electrode 32B includes electrode fingers 32Ba, a busbar 32Bb, which is connected to an end portion of each of the electrode fingers 32Ba in the X direction and extends in the Y direction, and an extension portion 32Bc, which extends in the X direction from the busbar 32Bb. Here, the first electrode 31B and the second electrode 32B are examples of the “functional electrode”.

The electrode fingers 31Ba and the electrode fingers 32Ba each have a rectangular or substantially rectangular shape and each include a longitudinal direction. The electrode finger 31Ba and the electrode finger 32Ba adjacent to the electrode finger 31Ba face each other in a direction orthogonal or substantially orthogonal to the longitudinal direction. The longitudinal direction of the electrode fingers 31Ba and 32Ba and the direction orthogonal or substantially orthogonal to the longitudinal direction of the electrode fingers 31Ba and 32Ba are directions crossing the thickness direction of the piezoelectric layer 20. Thus, it can be said that the electrode finger 31Ba and the electrode finger 32Ba adjacent to the electrode finger 31Ba face each other in the direction crossing the thickness direction of the piezoelectric layer 20.

Here, the case in which the electrode finger 31Ba and the electrode finger 32Ba are adjacent to each other is not the case in which the electrode finger 31Ba and the electrode finger 32Ba are disposed so as to be directly in contact with each other but the case in which the electrode finger 31Ba and the electrode finger 32Ba are disposed so as to be spaced from each other. In addition, when the electrode finger 31Ba and the electrode finger 32Ba are adjacent to each other, no electrode connected to a hot electrode or a ground electrode, including other electrode fingers 31Ba and 32Ba, is disposed between the electrode finger 31Ba and the electrode finger 32Ba. The number of pairs thereof does not have to be an integer and may be, for example, 1.5 or 2.5.

In Example Embodiment 7, the second portion 22 of the piezoelectric layer 20 includes the projections 22a on the lower surface 20b at respective positions adjacent to inside corners of the busbars 31Bb and 32Bb in the X direction. Accordingly, the thickness of the second portion 22 at the respective positions adjacent to the inside corners of the busbars in the X direction is larger than the thickness of the first portion 21. Thus, it is possible to reduce or prevent a strain from being caused on the piezoelectric layer 20 at the respective positions adjacent to the inside corners of the busbars in the X direction and to thus reduce or prevent the piezoelectric layer 20 from being damaged.

The piezoelectric device 10K according to Example Embodiment 7 can be manufactured by the same as or similar to those of the manufacturing method illustrated in FIG. 4 described above.

The functional electrodes and the piezoelectric layer according to Example Embodiment 7 may be combined with each example embodiment and modification described above.

As described above, in the piezoelectric device according to Example Embodiment 7, the at least one functional electrode includes an IDT electrode including a plurality of electrode fingers arranged in a predetermined direction. Also in this case, it is possible to reduce or prevent the piezoelectric layer 20 from being damaged.

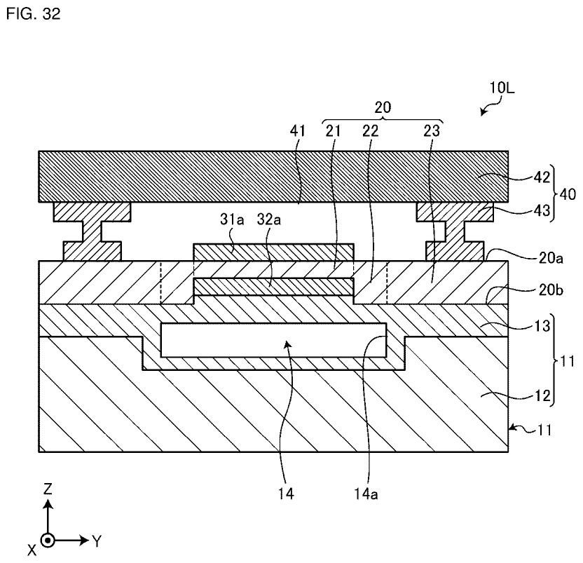

FIG. 32 is a schematic sectional view illustrating a piezoelectric device according to Example Embodiment 8 of the present invention. As illustrated in FIG. 32, a piezoelectric device 10L according to Example Embodiment 8 differs from the piezoelectric device according to Example Embodiment 1 in that an inert gas is filled in the space portion 14.

In Example Embodiment 8, the support 11 further includes the intermediate layer 13. The intermediate layer 13 is provided between the support substrate 12 and the piezoelectric layer 20 and covers the piezoelectric layer 20 side of the support substrate 12 and the lower surface 20b side of the piezoelectric layer 20. The intermediate layer 13 is made of an insulating material such as, for example, silicon oxide. In Example Embodiment 8 in FIG. 32, the space portion 14 is a sealed space surrounded by the intermediate layer 13. An inert gas such as, for example, argon is filled in the space portion 14. Accordingly, even when the piezoelectric device 10L is hot, it is possible to reduce or prevent the piezoelectric layer 20 from being dented due to atmospheric pressure and from coming into contact with the bottom surface of the space portion 14.

The piezoelectric device 10L further includes a package 40. The package 40 is provided on the upper surface 20a of the piezoelectric layer 20 so as to cover the upper electrode 31A. The package 40 is adhered to the portion of the upper surface 20a of the third portion 23 of the piezoelectric layer 20. In Example Embodiment in FIG. 32, the package 40 includes a package substrate 42 and an adhesion portion 43. The package substrate 42 is a substrate including a thickness in the Z direction. The material for the package substrate 42 is, for example, silicon. The adhesion portion 43 is a member provided on the piezoelectric layer 20 side of the package substrate 42. The shape of the adhesion portion 43 is a frame shape in plan view in the Z direction. The material for the adhesion portion 43 is, for example, a metal. The package 40 may be made of, for example, a metal or resin material. In addition, the adhesion portion 43 may be made of, for example, a resin. In addition, the adhesion portion 43 is not limited to a single layer and, for example, may be a metal multilayer body or a multilayer body of a metal and a resin.

A space 41 surrounded by the upper surface 20a of the piezoelectric layer 20 and the package 40 is located inside the package 40. The space 41 is sealed. Here, the pressure in the space 41 is equal or substantially equal to the pressure in the space portion 14.

When the pressure in the space portion 14 is smaller than the atmospheric pressure, a film stress that bends, toward the support 11 in the Z direction, the portions (the first portion 21 and the second portion 22) of the piezoelectric layer 20 overlapping the space portion 14 in plan view in the Z direction is applied to the portions of the piezoelectric layer 20. Alternatively, when the pressure in the space portion 14 is larger than the atmospheric pressure, a film stress that bends, toward the side opposite to the support 11 in the Z direction, the portions (the first portion 21 and the second portion 22) of the piezoelectric layer 20 overlapping the space portion 14 in plan view in the Z direction is applied to the portions of the piezoelectric layer 20. Here, the atmospheric pressure is the standard pressure, that is, 1.01325×10⁶ Pa. Thus, it is possible to further reduce or prevent the piezoelectric layer 20 from being damaged due to the pressure difference between the pressure in the space portion 14 and the atmospheric pressure in a process for manufacturing the piezoelectric device 10L.

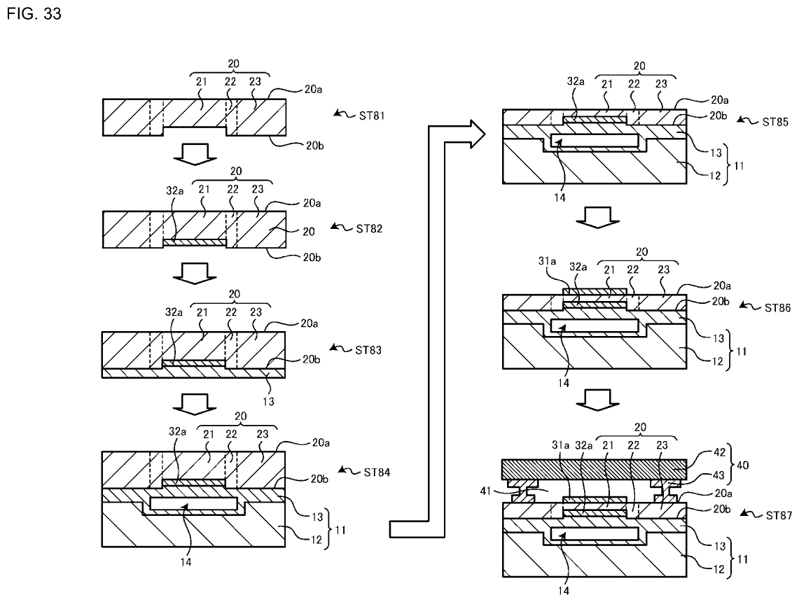

Next, an example of a method for manufacturing the piezoelectric device according to the present example embodiment will be described. FIG. 33 is an explanatory diagram for describing an example of a method for manufacturing the piezoelectric device according to Example Embodiment 8. In the description of the method for manufacturing the piezoelectric device according to Example Embodiment 8, matters overlapping those of the manufacturing method illustrated in FIG. 4 described above are omitted.

Similarly to the steps ST1 and ST2 in FIG. 4, the thickness of the first portion 21 of the piezoelectric layer 20 is reduced (step ST81). The lower electrode 32 is formed on the portion of the lower surface 20b of the first portion 21 of the piezoelectric layer 20 (step ST82).

Subsequently, the intermediate layer 13 is formed on the lower surface 20b of the piezoelectric layer 20 so as to cover the lower electrode 32 (step ST83). The intermediate layer 13 is made of a material such as, for example, silicon oxide by sputtering. An adhesion layer made of, for example, Ti or NiCr may be provided between the lower electrode 32 and the intermediate layer 13. In addition, the lower surface (surface opposite to the piezoelectric layer 20) of the intermediate layer 13 may be flattened by, for example, CMP as appropriate.

Subsequently, the support substrate 12 including the space portion 14 and an insulating film in one surface thereof is prepared, and the insulating film of the support substrate 12 and the intermediate layer 13 formed on the lower surface 20b of the piezoelectric layer 20 are connected to each other. Thus, the support substrate 12 and the piezoelectric layer 20 are attached to each other (step ST84). The support substrate 12 is connected to the piezoelectric layer 20 by, for example, direct bonding, plasma activated bonding, or atomic diffusion bonding. The step ST84 is performed in an atmosphere of an inert gas. Thus, the inert gas is filled in the space portion 14.

Then, similarly to the steps ST4 and ST5 in FIG. 4, the upper surface 20a of the piezoelectric layer 20 is ground and polished to thin the piezoelectric layer 20 (step ST85). The upper electrode 31 is formed on the upper surface 20a of the piezoelectric layer 20 (step ST86). In Example Embodiment 8, the thickness of the second portion 22 is larger than the thickness of the first portion. Thus, the displacement of the second portion, which is a portion not fixed by the functional electrodes, is reduced or prevented. Accordingly, it is possible to reduce or prevent the displacement of the piezoelectric layer 20. Here, the displacement ratio of the piezoelectric layer 20 after the step ST86 is, for example, preferably about −5% or more and about 5% or less. Here, the displacement ratio of the piezoelectric layer 20 is a ratio calculated by using the expression {(the average value of heights of the space portion 14 in a region overlapping the first portion 21)−(the average value of heights of the space portion 14 at the boundary 14a)}/(the average value of heights of the space portion 14 at the boundary 14a). Here, the height of the space portion 14 is the length of the space portion 14 in the Z direction, that is, the distance between surfaces exposed to the space portion 14 in the Z direction.

Subsequently, the package 40 is formed on the piezoelectric layer 20 (step ST87). The package 40 is connected to the portion of the upper surface 20a of the third portion of the piezoelectric layer 20 by, for example, metal bonding or direct bonding. In the example embodiment in FIG. 33, the package 40 is formed by using the following method, for example. First, the portion of the adhesion portion 43 on one side in the Z direction is formed on the portion of the upper surface 20a of the third portion of the piezoelectric layer 20. Subsequently, the portion of the adhesion portion 43 on the other side in the Z direction is formed on the surface of the package substrate 42 on the piezoelectric layer 20 side. Then, the portions of the adhesion portion 43 are connected to each other. Thus, it is possible to form the package 40 on the piezoelectric layer 20.

The piezoelectric device 10L according to the present example embodiment is manufactured by the above steps. The steps in FIG. 33 are merely schematically illustrated and can be changed as appropriate.

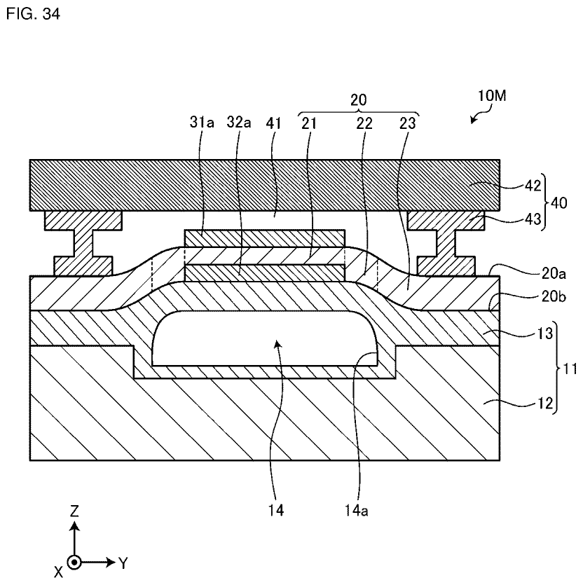

FIG. 34 is a schematic sectional view illustrating a piezoelectric device according to Modification 6 of Example Embodiment 8 of the present invention. As illustrated in FIG. 34, a piezoelectric device 10M according to Modification 6 differs from the piezoelectric device according to Example Embodiment 8 in that the piezoelectric layer 20 is bent toward the side opposite to the support 11 in the Z direction.

In Modification 6, in the second portion 22 of the piezoelectric layer 20, the piezoelectric layer 20 is bent toward the side opposite to the support 11 in the Z direction. In Modification 6, the thickness of the second portion 22 is larger than the thickness of the first portion 21. Thus, the displacement of the second portion 22, which is a portion not fixed by the functional electrodes, is inhibited. Accordingly, it is possible to reduce or prevent the displacement of the piezoelectric layer 20. In Modification 6, the displacement ratio of the piezoelectric layer 20 is, for example, more than about 0% and about 5% or less. In this case, it is possible to reduce or prevent the piezoelectric layer from being damaged due to temperature changes in a process for manufacturing the piezoelectric device 10M.

Here, the piezoelectric device 10M according to Modification 6 can be manufactured by using a method the same as or similar to that of the piezoelectric device 10L according to Example Embodiment 8.

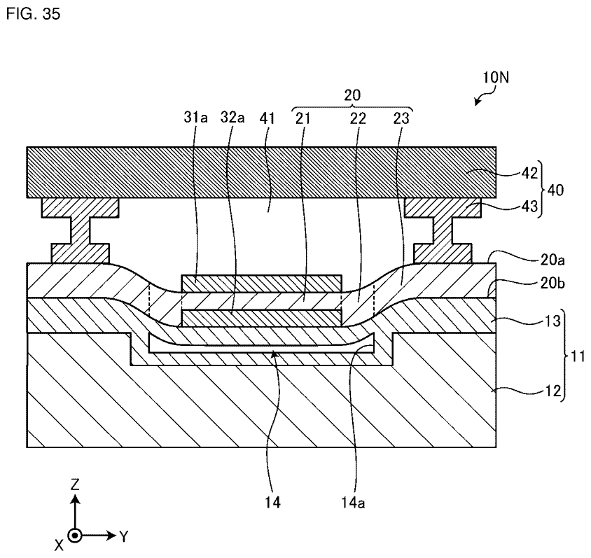

FIG. 35 is a schematic sectional view illustrating a piezoelectric device according to Modification 7 of Example Embodiment 8 of the present invention. As illustrated in FIG. 35, a piezoelectric device 10N according to Modification 7 differs from the piezoelectric device according to Example Embodiment 8 in that the piezoelectric layer 20 is bent toward the support 11 in the Z direction.

In Modification 7, in the second portion 22 of the piezoelectric layer 20, the piezoelectric layer 20 is bent toward the support 11 in the Z direction. In Modification 7, the thickness of the second portion 22 is larger than the thickness of the first portion 21. Thus, the displacement of the second portion 22, which is a portion not fixed by the functional electrodes, is reduced or prevented. Accordingly, it is possible to reduce or prevent the displacement of the piezoelectric layer 20. In Modification 7, the displacement ratio of the piezoelectric layer 20 is, for example, about-5% or more and less than about 0%. In this case, it is possible to reduce or prevent the piezoelectric layer from being damaged due to temperature changes in a process for manufacturing the piezoelectric device 10N.

Here, the piezoelectric device 10N according to Modification 7 can be manufactured by using a method the same as or similar to that of the piezoelectric device 10L according to Example Embodiment 8.

The example embodiments described above are intended to facilitate understanding of the present invention and are not intended to construe the present invention in any limiting manner. The present invention may be modified and improved without departing from the gist of the present invention and includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a piezoelectric layer including a thickness in a first direction, an upper surface being one surface of the piezoelectric layer in the first direction, and a lower surface being another surface of the piezoelectric layer in the first direction;
a support on a lower surface side of the piezoelectric layer; and
at least one functional electrode on at least one of the upper surface and the lower surface of the piezoelectric layer; wherein
the piezoelectric layer or the support includes a space portion in a region overlapping at least a portion of the at least one functional electrode; and
when a region of the piezoelectric layer overlapping the space portion and the at least one functional electrode in plan view in the first direction is a first portion and a region of the piezoelectric layer overlapping the space portion in plan view in the first direction and that does not overlap the at least one functional electrode in plan view in the first direction is a second portion, a maximum thickness of the second portion is larger than a minimum thickness of the first portion.

2. The piezoelectric device according to claim 1, wherein an average thickness of the second portion at a boundary between a region overlapping the space portion and a region not overlapping the space portion in plan view in the first direction is larger than an average thickness of the second portion at a boundary between a region overlapping the at least one functional electrode and a region not overlapping the at least one functional electrode in plan view in the first direction.

3. The piezoelectric device according to claim 1, wherein the maximum thickness of the second portion is larger than an average thickness of the at least one functional electrode.

4. The piezoelectric device according to claim 1, wherein the support is located on a first direction side of the space portion.

5. The piezoelectric device according to claim 1, wherein
the at least one functional electrode includes:
an upper electrode on the upper surface of the piezoelectric layer; and
a lower electrode on the lower surface of the piezoelectric layer, the lower electrode at least partially facing the upper electrode.

6. The piezoelectric device according to claim 5, wherein
a shape of a region where the upper electrode and the lower electrode overlap each other in plan view in a Z direction is a rectangular or substantially rectangular shape, in plan view in the first direction, including two pairs of sides extending in two respective directions crossing the first direction; and
a maximum thickness of the second portion at respective positions adjacent to corners of the rectangular or substantially rectangular shape in plan view in the first direction is larger than the minimum thickness of the first portion.

7. The piezoelectric device according to claim 1, wherein the at least one functional electrode includes an interdigital transducer (IDT) electrode including a plurality of electrode fingers arranged in a predetermined direction.

8. The piezoelectric device according to claim 1, wherein the piezoelectric layer includes lithium niobate, lithium tantalate, or quartz.

9. The piezoelectric device according to claim 1, wherein the at least one functional electrode includes a circular main electrode portion and an extension portion extending from the circular main electrode portion.

10. The piezoelectric device according to claim 1, wherein the at least one functional electrode includes aluminum, platinum, copper, tungsten, or molybdenum, or an alloy including at least one of aluminum, platinum, copper, tungsten, or molybdenum.

11. The piezoelectric device according to claim 1, wherein the at least one functional electrode includes an adhesive layer.

12. The piezoelectric device according to claim 11, wherein the adhesive layer includes titanium or nickel chromium alloy.

13. The piezoelectric device according to claim 1, wherein the support includes a support substrate.

14. The piezoelectric device according to claim 13, wherein the support substrate includes silicon or quartz crystal.

15. The piezoelectric device according to claim 1, wherein the space portion is provided in the piezoelectric layer.

16. The piezoelectric device according to claim 6, wherein the second portion of the piezoelectric layer includes projections on the lower surface thereof.

17. The piezoelectric device according to claim 7, wherein
the IDT electrode includes a pair of busbars; and
the second portion of the piezoelectric layer includes projections adjacent to inside corners of the pair of busbars.

18. The piezoelectric device according to claim 13, wherein
the support includes an intermediate layer between the support substrate and the piezoelectric layer;
the intermediate layer surrounds the space portion;
the space portion is sealed by the intermediate layer.

19. The piezoelectric device according to claim 18, wherein an inert gas is included in the space portion.

20. The piezoelectric device according to claim 18, wherein the intermediate layer includes silicon oxide.
